(19) United States
(12) Patent Application Publication
(10) Pub. No.: US 2016/0166959 A1
(43) Pub. Date: Jun. 16, 2016

(54) AIR FILTER FOR HIGH-EFFICIENCY PM2.5 CAPTURE

(71) Applicant: The Board of Trustees of the Leland Stanford Junior University, Palo Alto, CA (US)

(72) Inventors: Yi CUI, Stanford, CA (US); Rufan ZHANG, Stanford, CA (US); Chong LIU, Stanford, CA (US); Po-Chun HSU, Stanford, CA (US); Steven CHU, Stanford, CA (US)

(21) Appl. No.: 14/968,654

(22) Filed: Dec. 14, 2015

Related U.S. Application Data
(60) Provisional application No. 62/091,041, filed on Dec. 12, 2014.

(51) Int. Cl. B01D 39/08; C23C 14/34; B05D 1/00; B03C 3/34

(52) U.S. Cl. CPC B01D 39/08; B03C 3/34; C23C 14/3414; B05D 1/007

(57) ABSTRACT

Described here is an air filter comprising a substrate and a network of polymeric nanofibers deposited on the substrate, wherein the air filter a removal efficiency for PM_{2.5} of at least 70% when a light transmittance is below 50%. Also described here is an electric air filter comprising a first layer adapted to receive a first electric voltage, wherein the first layer comprises an organic fiber coated with a conductive material. Further described is an air filter for high temperature filtration, comprising a substrate and a network of polymeric nanofibers deposited on the substrate, wherein the air filter has a removal efficiency for PM_{2.5} of at least 70% at a temperature of a least 70° C.

### CROSS-REFERENCE TO RELATED APPLICATIONS

This application claims the benefit of U.S. Provisional Patent Application No. 62/091,041 filed Dec. 12, 2014, the content of which is incorporated herein by reference in its entirety.

### BACKGROUND

Particulate matter (PM) pollution in air affects people's living quality tremendously, and it poses a serious health threat to the public as well as influencing visibility, direct and indirect radiative forcing, climate, and ecosystems. PM is a complex mixture of extremely small particles and liquid droplets. Based on the particle size, PM is categorized by PM_{2.5} and PM₁₀ which refer to particle sizes below 2.5 μm and 10 μm, respectively. PM_{2.5} pollution is particularly harmful since it can penetrate human bronchi and lungs due to its small size. Hence, long term exposure to PM_{2.5} increases morbidity and mortality. Recently there have been serious PM pollution problems in developing countries with a large manufacturing industry such as China. FIGS. 1A and 1B shows images of a location in Beijing during clear and hazy days, respectively. During hazy days, the visibility decreased a lot and the air quality was unhealthy due to extreme high level of PM_{2.5}.

Measures taken by the public during hazy days are mostly focused on outdoor individual protection, such as using mask filters, which are often bulky and resistant to air flow. In indoor spaces, protection is available in modern commercial buildings through filtering in ventilation systems or central air conditioning; residential housing seldom have filtration protection from PM. Moreover, all these active air exchange by mechanical ventilation consumes enormous energy due to massive use of pumping systems. If staying indoors without sufficient air exchange, the indoor air quality is also of great concern. It would be ideal if passive air exchange, i.e., natural ventilation, by the wind through windows could be used for indoor air filtration. Owing to the large area of window, air exchange is very efficient. Protection at windows requires the air filters to not only possess a high PM capture ability but also a high optical transparency for natural lighting from sun and sight-viewing at the same time.

The PM_{2.5} pollution particles in air have complicated compositions including inorganic matter (such as SiO₂, SO₄²⁻ and NO₃⁻) and organic matter (such as organic carbon and elemental carbon) from diverse sources including soil dust, vehicular emission, coal combustion, secondary aerosols, industrial emission, and biomass burning. The behavior of PM particles are different due to their chemical compositions, morphologies and mechanical properties. Some rigid inorganic PM particles are mainly captured by interception and impaction on a filter surface. Some soft PM containing a lot of carbon compounds or water such as those from combustion exhaust would deform on filter surfaces and require stronger binding during the process of attaching to the filter. However, in existing air filter technology, not much work has been done to study the filter material properties. There are two types of air filters in common use. One is a porous membrane filter, which is similar to a water filtration filter (see FIG. 1C). This type of air filter is made by creating pores on solid substrate, it usually has very small pore size to filter out PM with larger sizes, and the porosity of this type of filter is low (<30%). Hence, the filtration efficiency is high though the pressure drop is large. Another type of air filter is fibrous air filter which captures PM particles by the combination of thick physical barriers and adhesion (see FIG. 1D). This type of filter usually has porosities >70% and is made of many layers of thick fibers of diverse diameters from several microns to tens of microns. To obtain a high efficiency, this type of filter is usually made very thick. The deficiency of the second type of filter is the bulkiness, non-transparency, and the compromise between air flow and filter efficiency.

In order to eliminate or reduce the emission of PM into the air, PM often needs to be removed from sources associated with high temperature. This calls for technology capable of high temperature air filtration. Further, high temperature dust removal from exhaust gas is desirable in industries and has recently attracted more attention. However, existing technology could not meet the requirement of high-efficiency PM_{2.5} removal at high temperature. As shown in FIG. 18D, most of the industrial dust collectors such as cyclones, scrubbers, and sedimentation tanks, are only effective for removing particles larger than 10 but they are ineffective for particles smaller than 10 Besides, the cyclones, spray towers and Venturi scrubbers consumes a lot of energy and have large flow resistance (i.e., the pressure drop is high) during operation. The electrostatic precipitators have high construction and operation cost and their PM removal efficiency depends on the PM properties such as sizes, charge states and conductivity, etc. Although micron-sized fibrous filters are relatively effective for small particles, most of the fibrous filters do not work at high temperature (usually <100° C.) and have large pressure drop.

As existing technology would not meet the requirements of high efficiency PM_{2.5} filters, there is a need for improvement.

### SUMMARY

Disclosed here is an improved polymer nanofiber filter technology, which has attractive attributes of high filtering efficiency, low resistance to air flow and light weight as shown in FIG. 1E. When it is needed, it can also have good optical transparency. It was found when surface chemistry of the air filter is optimized to match that of PM particles, the single fiber capture ability is enhanced much more than the existing fibrous filters. Therefore the material used in the air filter can be reduced significantly to a transparent level to provide both transparency to sunlight and sufficient airflow. Also, when the fiber diameter is decreased to nanometer scale, with the same packing density, the particle capture ability is significantly increased due to large surface area, which also ensures effective PM capture with much thinner air filter. The electric static charges injected into polymer nanofibers are also important for attracting PM particles to the surface. This improved filter can be applied to all types of air filtration situations such as personal masking, air conditioning, indoor air cleaning machines, building windows, outdoor applications, cars and industrial filtration. By controlling the surface chemistry and microstructure of the air filters, transparent ultrathin filters were archived, which have of ˜90% transparency with >95% removal, ˜60% transparency with >99% removal and ˜30% transparency with >99.97% removal of PM_{2.5} particles under extreme hazardous air quality condition. It can also be used in the applications without any optical transparency requirement.

High-Efficiency Nanofibrous Air Filter

One aspect of some embodiments of the invention described herein relates to an air filter comprising a substrate and a network of polymeric nanofibers deposited on the substrate, wherein the air filter has a light transmittance of at least 50% and a removal efficiency for PM_{2.5} of at least 70%.

In some embodiments, the polymeric nanofibers comprise a polymer comprising a repeating unit having a dipole moment of at least 0.5 Debye (D) or at least 1 D. In some embodiments, the polymeric nanofibers comprise a polymer comprising a repeating unit having a dipole moment of at least 2 D. In some embodiments, the polymeric nanofibers comprise a polymer comprising a repeating unit having a dipole moment of at least 3 D. In some embodiments, the polymeric nanofibers comprise a polymer comprising a repeating unit having a dipole moment of at least 3.5 D, at least 4 D, or at least 5 D, and up to 10 D, up to 12 D, or more. Examples of suitable repeating units include repeating units including polar groups, such as substituted alkyl groups (e.g., substituted with 1, 2, 3, or more halo groups or other polar groups listed below), substituted alkenyl groups (e.g., substituted with 1, 2, 3, or more halo groups or other polar groups listed below), substituted alkynyl groups (e.g., substituted with 1, 2, 3, or more halo groups or other polar groups listed below), substituted aryl groups (e.g., substituted with 1, 2, 3, or more halo groups or other polar groups listed below), hydroxyl groups, ketone groups, sulfone groups, aldehyde groups, ether groups, thio groups, cyano groups (or nitrile groups), nitro groups, amino groups, N-substituted amino groups, ammonium groups, N-substituted ammonium groups, amide groups, N-substituted amide groups, carboxy groups, alkylcarbonyloxy groups, alkenylcarbonyloxy groups, alkynylcarbonyloxy groups, arylcarbonyloxy groups, alkylcarbonylamino groups, N-substituted alkylcarbonylamino groups, alkenylcarbonylamino groups, N-substituted alkenylcarbonylamino groups, alkynylcarbonylamino groups, N-substituted alkynylcarbonylamino groups, arylcarbonylamino groups, N-substituted arylcarbonylamino groups, urea groups, epoxy groups, oxazolidone groups, and charged or hetero forms thereof. In some embodiments, the polymeric nanofibers comprise a polymer comprising a repeating unit having a ketone group and/or a sulfone group.

In some embodiments, the polymeric nanofibers comprise a polymer comprising a repeating unit which comprises a nitrile group. In some embodiments, the polymeric nanofibers comprise polyacrylonitrile (PAN). In some embodiments, the polymeric nanofibers comprise a polymer comprising a repeating unit which comprises polar functional groups (e.g., —CN, —OH, —CO—, —C—O—, —NO₂, —NH—, —NH₂, etc.). The higher dipole moment of the repeating unit of the polymer, the better adhesiveness of polymer to PM particles.

In some embodiments, the polymeric nanofibers have an average diameter of less than 1 micron. In some embodiments, the polymeric nanofibers have an average diameter of 10-900 nm. In some embodiments, the polymeric nanofibers have an average diameter of 20-800 nm. In some embodiments, the polymeric nanofibers have an average diameter of 30-700 nm. In some embodiments, the polymeric nanofibers have an average diameter of 50-500 nm. In some embodiments, the polymeric nanofibers have an average diameter of 100-300 nm.

In some embodiments, the polymeric nanofibers are electrospun onto the substrate.

In some embodiments, the polymeric nanofibers carry electric charges. In some embodiments, the polymeric nanofibers carry positive charges. In some embodiments, the polymeric nanofibers carry negative charges.

In some embodiments, the air filter has a light transmittance of at least 60%. In some embodiments, the air filter has a light transmittance of at least 70%. In some embodiments, the air filter has a light transmittance of at least 75%. In some embodiments, the air filter has a light transmittance of at least 80%. In some embodiments, the air filter has a light transmittance of at least 85%. In some embodiments, the air filter has a light transmittance of at least 90%. Transmittance values can be expressed by weighting the AM1.5 solar spectrum from 400 to 800 nm to obtain an average transmittance value. Transmittance values also can be expressed in terms of human vision or photometric-weighted transmittance, transmittance at a given wavelength or range of wavelengths in the visible range, such as 550 nm, or other wavelength or range of wavelengths.

In some embodiments, the air filter are used for applications which do not have optical transparency requirements. The air filter has a light transmittance less than 60%, or 30%, or 10% or 5%.

In some embodiments, the air filter has a removal efficiency for PM_{2.5} of at least 80%. In some embodiments, the air filter has a removal efficiency for PM_{2.5} of at least 90%. In some embodiments, the air filter has a removal efficiency for PM_{2.5} of at least 95%. In some embodiments, the air filter has a removal efficiency for PM_{2.5} of at least 98%. In some embodiments, the air filter has a removal efficiency for PM_{2.5} of at least 99%.

In some embodiments, multiple layers of the air filter might be used to achieve a removal efficiency of at least 80%. In some embodiments, multiple layers of the air filter has a removal efficiency for PM_{2.5} of at least 90%. In some embodiments, multiple layers of the air filter has a removal efficiency for PM_{2.5} of at least 95%. In some embodiments, multiple layers of the air filter has a removal efficiency for PM_{2.5} of at least 98%. In some embodiments, multiple layers of the air filter has a removal efficiency for PM_{2.5} of at least 99%.

In some embodiments, the air filter has a removal efficiency for PM_{10-2.5} of at least 80%. In some embodiments, the air filter has a removal efficiency for PM_{10-2.5} of at least 90%. In some embodiments, the air filter has a removal efficiency for PM_{10-2.5} of at least 95%. In some embodiments, the air filter has a removal efficiency for PM_{10-2.5} of at least 98%. In some embodiments, the air filter has a removal efficiency for PM_{10-2.5} of at least 99%.

In some embodiments, the air filter maintains its filtering efficiency under humid conditions. In some embodiments, the air filter has a removal efficiency for PM_{2.5} of at least 90% at a relative humidity of 60% at 25° C. In some embodiments, the air filter has a removal efficiency for PM_{2.5} of at least 90% at a relative humidity of 70% at 25° C. In some embodiments, the air filter has a removal efficiency for PM_{2.5} of at least 90% at a relative humidity of 80% at 25° C. In some embodiments, the air filter has a removal efficiency for PM_{2.5} of at least 90% at a relative humidity of 90% at 25° C.

In some embodiments, the air filter maintains its filtering efficiency after long-term exposure to PM_{2.5}. In some embodiments, the air filter has a removal efficiency for PM_{2.5} of at least 90% after 50 hours of exposure to air having an average PM_{2.5} index of 300 and an average wind speed of 1 mile/hour. In some embodiments, the air filter has a removal efficiency for PM_{2.5} of at least 90% after 100 hours of exposure to air having an average PM_{2.5} index of 300 and an average wind speed of 1 mile/hour. In some embodiments, the air filter has a removal efficiency for PM_{2.5} of at least 90% after 200 hours of exposure to air having an average PM_{2.5} index of 300 and an average wind speed of 1 mile/hour.

In some embodiments, the air filter further comprises another or more materials. In some embodiments, the air filter further comprises a catalyst (e.g., TiO₂, MoS₂) adapted for degrading the PM absorbed on the polymeric nanofibers. In some embodiments, the air filter further comprises an anti-biopathogen material (e.g., Ag) adapted for killing bacteria and virus absorbed on the polymeric nanofibers. In some embodiments, the air filter further comprises materials adapted for absorbing and/or degrading other air pollutant (e.g., aldehyde, NOₓ and SOₓ).

Another aspect of some embodiments of the invention described herein relates to an air filtering device comprising the air filter described herein. In some embodiments, the air filter is a removable, detachable, and/or replaceable.

In some embodiments, the air filtering device is a passive air filtering device. In some embodiments, the air filtering device is a window screen. In some embodiments, the air filtering device is a wearable mask. In some embodiments, the air filtering device is a helmet. In some embodiments, the air filtering device is a nose filter. In some embodiments, the air filtering device is building air handling system. In some embodiments, the air filtering device is car air conditioning system. In some embodiments, the air filtering device is industrial exhaust filtration system. In some embodiments, the air filtering device is clean room filtration system. In some embodiments, the air filtering device is hospital air cleaning system. In some embodiments, the air filtering device is a net for outdoor filtering. In some embodiments, the air filtering device is a cigarette filter.

A further aspect of some embodiments of the invention described herein relates to a method for making the air filter described herein, comprising electrospinning the polymeric nanofibers onto the substrate from a polymer solution. In some embodiments, the polymer solution comprises 1-20 wt. % of the polymer. In some embodiments, the polymer solution comprises 3-15 wt. % of the polymer. In some embodiments, the polymer solution comprises 5-10 wt. % of the polymer.

A further aspect of some embodiments of the invention described herein relates to a method for making an air filtering device, comprising incorporating the air filter described herein into a window screen. A further aspect of some embodiments of the invention described herein relates to a method for making an air filtering device, comprising incorporating the air filter described herein into a wearable mask. A further aspect of some embodiments of the invention described herein relates to a method for improving indoor air quality, comprising installing the window screen described herein in a window frame.

Electric Air Filter

Also disclosed here is an electric/conducting air filter. Accordingly, one aspect of some embodiments of the invention described herein relates to an electric air filter comprising a first layer adapted to receive a first electric voltage, wherein the first layer comprises an organic fiber coated with a conductive material.

In some embodiments, the first layer comprises a microfiber having at least one lateral dimension of 1000 micron or less. In some embodiments, the first layer comprises a nanofiber having at least one lateral dimension of 1 micron or less. In some embodiments, the microfiber or nanofiber comprise a polymer comprising a repeating unit which comprises polar functional groups (e.g., —CN, —OH, —CO—, —C—O—C—, —SO₂—, —NO₂, —NH—, —NH₂). The higher dipole moment of the repeating unit of the polymer, the better adhesiveness of polymer to PM particles. In some embodiments, the microfiber or nanofiber comprise a polymer selected from nylon, polyacrylonitrile (PAN), polyvinylpyrrolidone (PVP), polystyrene (PS), or polyethylene (PE).

In some embodiment, the conductive material comprises metal. In some embodiment, the conductive material comprises elemental metal such as Cu. In some embodiment, the conductive material comprises conducting carbon, carbon nanotubes, graphene, graphene oxide or graphite. In some embodiment, the conductive material comprises metal oxide. In some embodiment, the conductive material comprises metal nitride. In some embodiment, the conductive material comprises a conductive polymer. In some embodiment, the conductive material is adapted to maintain a high conductivity for months or even years in air.

In some embodiment, the organic fiber is partially coated with the conductive material. In some embodiments, the organic fiber comprises a coated side and an uncoated side.

In some embodiment, the organic fiber is fully coated with the conductive material, wherein the outer surface of the conductive coating is further functionalized. In some embodiments, the outer surface of conductive coating is functionalized with a polar group to increase affinity for PM particles.

In some embodiment, the electrical air filter further comprises a second layer adapted to receive a second electric voltage, wherein the second layer is identical to or different from the first layer. In some embodiments, the first layer and the second layer are disposed parallel to each other in the electric air filter. In some embodiments, a positive voltage is applied on the first layer and a negative or neutral voltage is applied on the second layer. In some embodiments, a negative voltage is applied on the first layer and a positive or neutral voltage is applied on the second layer. In some embodiments, the air flow passes through the first layer before contacting the second layer. In some embodiments, the air flow passes through the second layer before contacting the first layer.

In some embodiment, the electrical air filter has a removal efficiency for PM_{2.5} of at least 80%. In some embodiments, the electrical air filter has a removal efficiency for PM_{2.5} of at least 90%. In some embodiments, the electrical air filter has a removal efficiency for PM_{2.5} of at least 95%. In some embodiments, the electrical air filter has a removal efficiency for PM_{2.5} of at least 98%. In some embodiments, the electrical air filter has a removal efficiency for PM_{2.5} of at least 99%.

In some embodiment, the electrical air filter has a removal efficiency for PM_{10-2.5} of at least 80%. In some embodiments, the electrical air filter has a removal efficiency for PM_{10-2.5} of at least 90%. In some embodiments, the electrical air filter has a removal efficiency for PM_{10-2.5} of at least 95%. In some embodiments, the electrical air filter has a removal efficiency for PM_{10-2.5} of at least 98%. In some embodiments, the electrical air filter has a removal efficiency for PM_{10-2.5} of at least 99%.

Another aspect of some embodiments of the invention described herein relates to an air filtering device comprising the electric air filter described herein. In some embodiments, the air filtering device is a ventilation system. In some embodiments, the air filtering device is an air-conditioning system. In some embodiments, the air filtering device is an automotive cabin air filter. In some embodiments, the air filtering device is a window screen.

A further aspect of some embodiments of the invention described herein relates to a method for making the electric air filter. In some embodiments, the method comprises sputter coating a metal or metal oxide onto a microfiber or nanofiber. In some embodiments, the microfiber or nanofiber is partially coated with the metal or metal oxide by directional sputter coating. In some embodiments, the microfiber or nanofiber is fully coated with the metal or metal oxide.

In some embodiments, the method comprises comprising treating the outer surface of the metal or metal oxide coating to generate a reactive group, and reacting said reactive group with an organic compound to functionalize the outer surface of the metal or metal oxide coating to increase affinity for PM particles. In some embodiments, the outer surface of the metal or metal oxide coating is treated with air plasma to generate —OH group. In some embodiments, the —OH group is reacted with a silane derivative (e.g., 3-cyanopropyltrichlorosilane) to functionalize the outer surface of the metal or metal oxide coating. Other suitable functional groups include those having high polarity and high dipole moment (e.g., —CN, —OH, —CO—, —NO₂, —NH—, —NH₂). The higher dipole moment, the better adhesiveness to PM particles.

A further aspect of some embodiments of the invention described herein relates to a method for filtering PM particles using the electric air filter, comprising applying an electric voltage on the first layer of the electric air filter. In some embodiments where the organic fiber in the first layer comprises a coated side and an uncoated side, the method can comprise placing the electric air filter in a manner to allow the uncoated side to face the direction of air flow.

In some embodiments, a positive electric voltage is applied on the first layer. In some embodiments, a negative electric voltage is applied on the first layer. In some embodiments, a positive voltage is applied on the first layer and a negative or neutral voltage is applied on the second layer. In some embodiments, a negative voltage is applied on the first layer and a positive or neutral voltage is applied on the second layer.

Nanofibrous Air Filters with High Temperature Stability for Efficient PM_{2.5} Removal from Pollution Sources

Another aspect of some embodiments of the invention described herein relates to an air filter for high temperature filtration, comprising a substrate and a network of polymeric nanofibers deposited on the substrate, wherein the air filter has a removal efficiency for PM_{2.5} of at least 70% at an operating temperature at least 70° C.

In some embodiments, the polymeric nanofibers comprise a polymer comprising a repeating unit having a dipole moment of at least 1 D, at least 2 D, or at least 3 D, or at least 4 D, or at least 5 D, or at least 6 D, and up to 10 D, up to 12 D, or more. Examples of suitable repeating units include repeating units including polar groups, such as substituted alkyl groups (e.g., substituted with 1, 2, 3, or more halo groups or other polar groups listed below), substituted alkenyl groups (e.g., substituted with 1, 2, 3, or more halo groups or other polar groups listed below), substituted alkynyl groups (e.g., substituted with 1, 2, 3, or more halo groups or other polar groups listed below), substituted aryl groups (e.g., substituted with 1, 2, 3, or more halo groups or other polar groups listed below), hydroxyl groups, ketone groups, sulfone groups, aldehyde groups, ether groups, thio groups, cyano groups (or nitrile groups), nitro groups, amino groups, N-substituted amino groups, ammonium groups, N-substituted ammonium groups, amide groups, N-substituted amide groups, carboxy groups, alkylcarbonyloxy groups, alkenylcarbonyloxy groups, alkynylcarbonyloxy groups, arylcarbonyloxy groups, alkylcarbonylamino groups, N-substituted alkylcarbonylamino groups, alkenylcarbonylamino groups, N-substituted alkenylcarbonylamino groups, alkynylcarbonylamino groups, N-substituted alkynylcarbonylamino groups, arylcarbonylamino groups, N-substituted arylcarbonylamino groups, urea groups, epoxy groups, oxazolidone groups, and charged or hetero forms thereof. In some embodiments, the polymeric nanofibers comprise a polymer comprising a repeating unit having a ketone group and/or a sulfone group.

In some embodiments, the polymeric nanofibers comprise a polymer comprising a repeating unit which comprises an imide group. In some embodiments, the polymeric nanofibers comprise polyimide (PI). In some embodiments, the polymeric nanofibers comprise a polymer comprising a repeating unit which comprises a nitrile group. In some embodiments, the polymeric nanofibers comprise polyacrylonitrile (PAN). In some embodiments, the polymeric nanofibers comprise poly(p-phenylene sulfide). In some embodiments, the polymeric nanofibers comprise poly-p-phenylene terephthalamide. In some embodiments, the polymeric nanofibers comprise polytetrafluoroethylene. In some embodiments, the polymeric nanofibers comprise a polymer comprising a repeating unit which comprises polar functional groups (e.g., —CN, —OH, —CO—, —NO₂, —NH—, —NH₂, etc.). The higher dipole moment of the repeating unit of the polymer, the better adhesiveness of polymer to PM particles.

In some embodiments, the polymeric nanofibers have an average diameter of less than 1 micron. In some embodiments, the polymeric nanofibers have an average diameter of 10-900 nm. In some embodiments, the polymeric nanofibers have an average diameter of 20-800 nm. In some embodiments, the polymeric nanofibers have an average diameter of 30-700 nm. In some embodiments, the polymeric nanofibers have an average diameter of 50-500 nm. In some embodiments, the polymeric nanofibers have an average diameter of 100-300 nm.

In some embodiments, the polymeric nanofibers are electrospun onto the substrate.

In some embodiments, the polymeric nanofibers carry electric charges. In some embodiments, the polymeric nanofibers carry positive charges. In some embodiments, the polymeric nanofibers carry negative charges.

In some embodiments, the air filter has a light transmittance of at least 30%, or at least 40%, or at least 50%, or at least 60%, or at least 70%, or at least 80%, or at least 90%. Transmittance values can be expressed by weighting the AM1.5 solar spectrum from 400 to 800 nm to obtain an average transmittance value. Transmittance values also can be expressed in terms of human vision or photometric-weighted transmittance, transmittance at a given wavelength or range of wavelengths in the visible range, such as 550 nm, or other wavelength or range of wavelengths.

In some embodiments, the air filter are used for applications which do not have optical transparency requirements. The air filter has a light transmittance less than 60%, or 30%, or 10% or 5%.

In some embodiments, at an operating temperature of 70° C. the air filter has a removal efficiency for PM_{2.5} of at least 70%, or at least 80%, or at least 90%, or at least 95%, or at least 98%, or at least 99%. In some embodiments, at an operating temperature of 150° C. the air filter has a removal efficiency for PM_{2.5} of at least 70%, or at least 80%, or at least 90%, or at least 95%, or at least 98%, or at least 99%. In some embodiments, at an operating temperature of 200° C. the air filter has a removal efficiency for PM_{2.5} of at least 70%, or at least 80%, or at least 90%, or at least 95%, or at least 98%, or at least 99%. In some embodiments, at an operating temperature of 250° C. the air filter has a removal efficiency for PM_{2.5} of at least 70%, or at least 80%, or at least 90%, or at least 95%, or at least 98%, or at least 99%. In some embodiments, at an operating temperature of 300° C. the air filter has a removal efficiency for PM_{2.5} of at least 70%, or at least 80%, or at least 90%, or at least 95%, or at least 98%, or at least 99%. In some embodiments, at an operating temperature of 350° C. the air filter has a removal efficiency for PM_{2.5} of at least 70%, or at least 80%, or at least 90%, or at least 95%, or at least 98%, or at least 99%.

In some embodiments, at an operating temperature of 70° C. the air filter has a removal efficiency for PM_{10-2.5} of at least 70%, or at least 80%, or at least 90%, or at least 95%, or at least 98%, or at least 99%. In some embodiments, at an operating temperature of 150° C. the air filter has a removal efficiency for PM_{10-2.5} of at least 80%, or at least 90%, or at least 95%, or at least 98%, or at least 99%. In some embodiments, at an operating temperature of 200° C. the air filter has a removal efficiency for PM_{10-2.5} of at least 80%, or at least 90%, or at least 95%, or at least 98%, or at least 99%. In some embodiments, at an operating temperature of 250° C. the air filter has a removal efficiency for PM_{10-2.5} of at least 80%, or at least 90%, or at least 95%, or at least 98%, or at least 99%. In some embodiments, at an operating temperature of 300° C. the air filter has a removal efficiency for PM_{10-2.5} of at least 80%, or at least 90%, or at least 95%, or at least 98%, or at least 99%. In some embodiments, at an operating temperature of 350° C. the air filter has a removal efficiency for PM_{10-2.5} of at least 80%, or at least 90%, or at least 95%, or at least 98%, or at least 99%.

In some embodiments, the air filter has a pressure drop of 500 Pa or less, 300 Pa or less, or 200 Pa or less, or 100 Pa or less, or 50 Pa or less, at a gas velocity of 0.2 m/s. In some embodiments, the air filter has a pressure drop of 500 Pa or less, or 300 Pa or less, or 200 Pa or less, or 100 Pa or less, or 50 Pa or less, at a gas velocity of 0.4 m/s. In some embodiments, the air filter has a pressure drop of 700 Pa or less, or 500 Pa or less, or 300 Pa or less, or 200 Pa or less, or 100 Pa or less, at a gas velocity of 0.6 m/s. In some embodiments, the air filter has a pressure drop of 700 Pa or less, or 500 Pa or less, or 300 Pa or less, or 200 Pa or less, or 100 Pa or less, at a gas velocity of 0.8 m/s. In some embodiments, the air filter has a pressure drop of 1000 Pa or less, or 700 Pa or less, or 500 Pa or less, or 300 Pa or less, or 200 Pa or less, or 100 Pa or less, at a gas velocity of 1.0 m/s.

In some embodiments, the air filter maintains its filtering efficiency after long-term exposure to PM_{2.5} at high temperature. In some embodiments, the air filter has a removal efficiency for PM_{2.5} of at least 80%, or at least 90%, or at least 95%, or at least 98%, or at least 99%, after 50 hours of exposure to air having an average PM_{2.5} index of 300 and an average wind speed of 0.2 m/s at an operating temperature of 200° C. In some embodiments, the air filter has a removal efficiency for PM_{2.5} of at least 80%, or at least 90%, or at least 95%, or at least 98%, or at least 99%, after 100 hours of exposure to air having an average PM_{2.5} index of 300 and an average wind speed of 0.2 m/s at an operating temperature of 200° C. In some embodiments, the air filter has a removal efficiency for PM_{2.5} of at least 80%, or at least 90%, or at least 95%, or at least 98%, or at least 99%, after 200 hours of exposure to air having an average PM_{2.5} index of 300 and an average wind speed of 0.2 m/s at an operating temperature of 200° C.

In some embodiments, the air filter has a removal efficiency of at least 80%, or at least 90%, or at least 95%, or at least 98%, or at least 99%, for removing PM_{2.5} particles from car exhaust gas having a temperature of 50˜80° C. and a gas velocity of 2˜3 m/s. In some embodiments, the air filter has a removal efficiency of at least 80%, or at least 90%, or at least 95%, or at least 98%, or at least 99%, for removing PM_{10-2.5} particles from car exhaust gas having a temperature of 50˜80° C. and a gas velocity of 2˜3 m/s.

Another aspect of some embodiments of the invention described herein relates to an air filtering device for removing high temperature PM_{2.5} particles from pollution sources comprising the air filter described herein. In some embodiments, the air filter is a removable, detachable, and/or replaceable.

In some embodiments, the air filtering device for removing high temperature PM_{2.5} particles from pollution sources is an exhaust air filter. In some embodiments, the air filtering device is a vehicle exhaust filter. In some embodiments, the air filtering device is an industrial exhaust filter. In some embodiments, the air filtering device is a power plant exhaust filter.

A further aspect of some embodiments of the invention described herein relates to a method for making the air filter configured for high temperature filtration, comprising electrospinning the polymeric nanofibers onto the substrate from a polymer solution. In some embodiments, the polymer solution comprises 1-30 wt. % of the polymer. In some embodiments, the polymer solution comprises 2-20 wt. % of the polymer. In some embodiments, the polymer solution comprises 3-15 wt. % of the polymer. In some embodiments, the polymer solution comprises 5-10 wt. % of the polymer.

A further aspect of some embodiments of the invention described herein relates to a method for making a high-temperature air filtering device, comprising incorporating the air filter described herein into a vehicle exhaust filter. A further aspect of some embodiments of the invention described herein relates to a method for making a high-temperature air filtering device, comprising incorporating the air filter described herein into an industrial exhaust filter. A further aspect of some embodiments of the invention described herein relates to a method for making a high-temperature air filtering device, comprising incorporating the air filter described herein into a power plant exhaust filter.

These and other features, together with the organization and manner of operation thereof, will become apparent from the following detailed description when taken in conjunction with the accompanying drawings.

### BRIEF DESCRIPTION OF THE DRAWINGS

FIGS. 1A-1E show photographs of PM pollution and schematics of existing air filters comparing to transparent air filter. (FIG. 1A) Photo of a random place in Beijing during sunny day. (FIG. 1B) Photo of the same place in Beijing during hazy day with hazardous PM_{2.5} level. (FIG. 1C) Schematics of porous air filter capturing PM particles by size exclusion. (FIG. 1D) Schematics of bulky fibrous air filter capturing PM particles by thick physical barrier and adhesion. (FIG. 1E) Schematics of transparent air filters that capture PM particles by strong surface adhesion and allowing a high light and air penetration.

FIGS. 2A-2F show performance of PM_{2.5} capture by transparent air filters with different surfaces. (FIG. 2A) Schematics showing the fabrication of transparent air filter by electrospinning. (FIG. 2B) Molecular model and formula of different polymers including PAN, PVP, PS, PVA and PP with calculated dipole moments of the repeating units of each polymer. (FIG. 2C) SEM images of PAN, PVP, PS, PVA and PP transparent filters before filtration. (FIG. 2D) SEM images of PAN, PVP, PS, PVA and PP transparent filters after filtration showing the PM attachment. Scale bars in (c-d) 5 μm. (FIG. 2E) Removal efficiency comparison between PAN, PVP, PS, PVA, PP carbon and copper transparent filters with same fiber diameter of ˜200 nm and same transmittance of ˜70%. (FIG. 2F) Demonstration of using transparent filter to shut off PM from the outdoor (right bottle) from entering the indoor (left bottle) environment.

FIGS. 3A-3F show transparency and air flow evaluation of transparent air filters. (FIG. 3A) Photographs of PAN transparent air filters at different transparency. (FIG. 3B) PM_{2.5} removal efficiencies of PAN, PVP, PS and PVA transparent filters at different transmittances. (FIG. 3C) PM_{10-2.5} removal efficiencies of PAN, PVP, PS and PVA transparent filters at different transmittances. (FIG. 3D) Photograph showing that the transparent filter can lead to efficient air exchange demonstrated by an electric fan. (FIG. 3E) Schematics showing the setup for the measurement of pressure drop of air filters. (FIG. 3F) Table summarizing the transmittance, efficiency, pressure drop and quality factor of transparent air filters comparing to commercial air filters.

FIGS. 4A-4J show in-situ time evolution study of PM capture by PAN transparent filter. (FIGS. 4A-4D) In-situ study of PM capture by PAN nanofiber characterized by OM showing filter morphologies at different time sequences during a continuous feed. Scale bars 20 μm. (FIGS. 4A-4H) Schematics showing the mechanism of PM capture by nanofibrous filter at different time sequences. (FIG. 4I) SEM image showing the detailed morphologies of attached soft PM which formed a coating layer wrapping around the PAN nanofiber. Scale bar 1 μm. (FIG. 4J) SEM image showing that the nanofiber junction have more PM aggregated to form bigger particles. Scale bar 1 μm.

FIGS. 5A-5J show smoke PM composition analysis by XPS, FTIR, TEM and EELS. (FIG. 5A) XPS characterization of PM particle showing the C 1s, O 1s and N 1s peak analysis and composition ratio. (FIG. 5B) FTIR characterization of PM particle showing the existing functional groups. (FIG. 5C) TEM images showing the morphologies of PM particles captured on PAN filter. (FIG. 5D) TEM image of the PM particle captured on PAN nanofiber used for EELS analysis. (FIGS. 5E-5F) EELS data of position e and f corresponding to PM particle and PAN fiber. (FIGS. 5G-5I) Extracted EELS data on different positions: (FIG. 5G) surface of PM particle; (FIG. 5H) bulk of PM particle and (FIG. 5I) PAN fiber. (FIG. 5J) Schematic showing PM particle compositions with nonpolar functional groups (C—C, C—H and C═C) inside and polar functional groups (C═O, C—O and C—N) outside.

FIGS. 6A-6E show PAN transparent filter long term performance and field test (Beijing) performance. (FIG. 6A) The long term PM_{2.5} and PM_{10-2.5} removal efficiencies by PAN transparent filter of 70% transmittance under continuous hazardous level of PM pollution. (FIGS. 6B-6C) SEM showing the PAN transparent air filter morphology after 100 hours' PM capture test. The scale bars are 50 μm and 10 μm, respectively (FIGS. 6D-6E) The PM_{2.5} and PM_{10-2.5} removal efficiencies of PAN and PS transparent filters with different transmittance compared with commercial-1 and commercial-2 mask. Tests were done in Beijing on Jul. 3, 2014 under air quality condition of PM_{2.5} index >300.

FIGS. 7A-7B show performance comparison between nanofibrous filters made from different polymers in capturing rigid dust PM and soft smoke PM. (FIG. 7A) PM_{2.5} and PM_{10-2.5} removal efficiencies of PAN, PVP, PS and PVA to dust PM particles and smoke PM particles. (FIG. 7B) SEM image showing PAN nanofibrous filter after capturing dust PM particles.

FIGS. 8A-8D show diameter dependence of PAN nanofibrous filters performance. (FIGS. 8A-8C) SEM images of PAN nanofibrous filters with diameters of 200 nm, 700 nm and 1.5 p.m. Scale bars are 5 p.m. (FIG. 8D) PM_{2.5} and PM_{10-2.5} removal efficiencies of PAN nanofibrous filters with diameters of 200 nm, 700 nm and 1.5 p.m.

FIGS. 9A-9D shows energy-dispersive X-ray spectroscopy (EDX) of PAN nanofibers after PM capture. (FIG. 9A) SEM image of PAN nanofibers with captured PM particles. (FIGS. 9B-9D) EDX mapping of element C, N and O.

FIGS. 10A-10D show SEM images of commercial filters. (FIG. 10A) Commercial-1, (FIG. 10B) Commercial-2, (FIG. 10C) Commercial-3 and (FIG. 10D) Commercial-4. Scale bars are 50 μm.

FIG. 11 shows wind velocity dependence of the PM_{2.5} and PM_{10-2.5} removal efficiencies of nanofibrous filters made from PAN, PVP, PS and PVA.

FIG. 12 shows humidity dependence of the PM_{2.5} and PM_{10-2.5} removal efficiencies of nanofibrous filters made from PAN, PVP, PS and PVA.

FIG. 13 shows summary of the transmittance, efficiency, pressure drop and quality factor of transparent PAN air filters comparing to commercial air filters.

FIG. 14A shows a schematic diagram of an example conducting air filter. During filtration, a negative voltage (0 to −10 kV) is added to the front electrode and a positive voltage is added to the back electrode (0 to +10 kV). FIG. 14B shows schematic diagrams of the first and second material synthesis options for the conducting air filter.

FIG. 15A shows an SEM image of an example Cu-sputter microfiber. FIG. 15B shows a schematic diagram of the first material synthesis option for the conducting air filter.

FIG. 16 shows SEM images of an example Cu-coated and functionalized nylon nanofiber.

FIG. 17 shows performance of an example electric air filter.

FIGS. 18A-18D show sources and temperature distribution of PM and the PM removal performance of different industrial dust collectors. (FIG. 18A) Photograph of chimney exhaust containing a large amount of high temperature PM particles (Yulin, China). (FIG. 18B) Sources of PM_{2.5} in Beijing. (FIG. 18C) Temperature and PM concentration distribution of various high temperature PM sources. (FIG. 18D) Comparison of PM removal performance of different industrial dust collectors. A, baffled settling chamber; B, cyclone “off the shelf”; C, carefully designed cyclone; D, electrostatic precipitator; E, spray tower; F, Venturi scrubber; G, bag filter.

FIGS. 19A-19O show structure and filtration performance of PI nanofibrous air filters at room temperature. (FIG. 19A) General molecular structure of PI. (FIG. 19B) Schematics of fabricating transparent PI air filters by electrospinning. (FIG. 19C) Photograph of a typical transparent PI air filter with optical transmittance of 70%. (FIG. 19D) OM image of a transparent PI air filter. (FIGS. 19E-19G) SEM images of PI air filters with different magnification. (FIG. 19H) SEM image of a PI air filter after filtration with PM particles. (FIG. 19I) OM image of a PI air filter after filtration with PM particles. (FIG. 19J) Removal efficiency of PI air filters with optical transmittance of 50% for PM particles with different sizes. (FIG. 19K) Demonstration of using PI air filter to block the PM from the sources (left bottle) entering the environment (right bottle). (FIGS. 19L-19O) In situ evolution study of PM capture by PI air filter under OM at different time sequences during a continuous feed of PM gas. The timescales for (FIGS. 19L-19O) is 0, 5, 60, 150 s, respectively.

FIGS. 20A-20G show thermal stability of PI air filters and set-up of high temperature PM removal efficiency measurement. (FIGS. 20A-20F) Structure and morphology comparison of PI air filters at different temperature. (FIG. 20G) Schematic illustration of the set-up for high temperature PM removal efficiency measurement.

FIGS. 21A-21D show PM removal efficiency comparison of different air filters. (FIG. 21A) PM_{2.5} removal efficiency comparison of PI air filters with different transparency. Here, PI-45 means PI air filter with optical transmittance of 45%, and others have similar meanings. (FIG. 21B) PM_{10-2.5} removal efficiency comparison of PI air filters with different optical transmittance. (FIG. 21C) PM_{2.5} removal efficiency comparison of different air filters made of different materials. Here, “Com-” means commercial air filter. (FIG. 21D) PM_{10-2.5} removal efficiency comparison of different air filters made of different materials.

FIGS. 22A-22C show transparency and pressure drop comparison of transparent PI air filters with different transmittance. (FIG. 22A) Photographs of PI transparent air filters with different transmittance. (FIG. 22B) Relationship of pressure drop and transmittance at different gas velocity for PI filters. (FIG. 22C) Comparison of pressure drop of different air filters.

FIGS. 23A-23C show long-term and field-test performance of PI air filters. (FIG. 23A) The long-term PM_{2.5} and PM_{10-2.5} removal efficiency by PI air filters with transmittance of 50% under continuous hazardous level of PM pollution. (FIG. 23B) PM number concentration measurement of car exhaust without air filter. (FIG. 23C) PM number concentration measurement of car exhaust with air filter. The inset shows a stainless steel pipe coated with a PI filter with transmittance of 50% shown by the red circle in c.

FIG. 24 shows size distribution of PM particles generated by incense burning over time.

FIG. 25 shows structure and morphology comparison of different air filters at different temperature.

FIG. 26 shows structure and morphology comparison of different air filters at different temperature.

FIG. 27 shows schematic of pressure drop measurement.

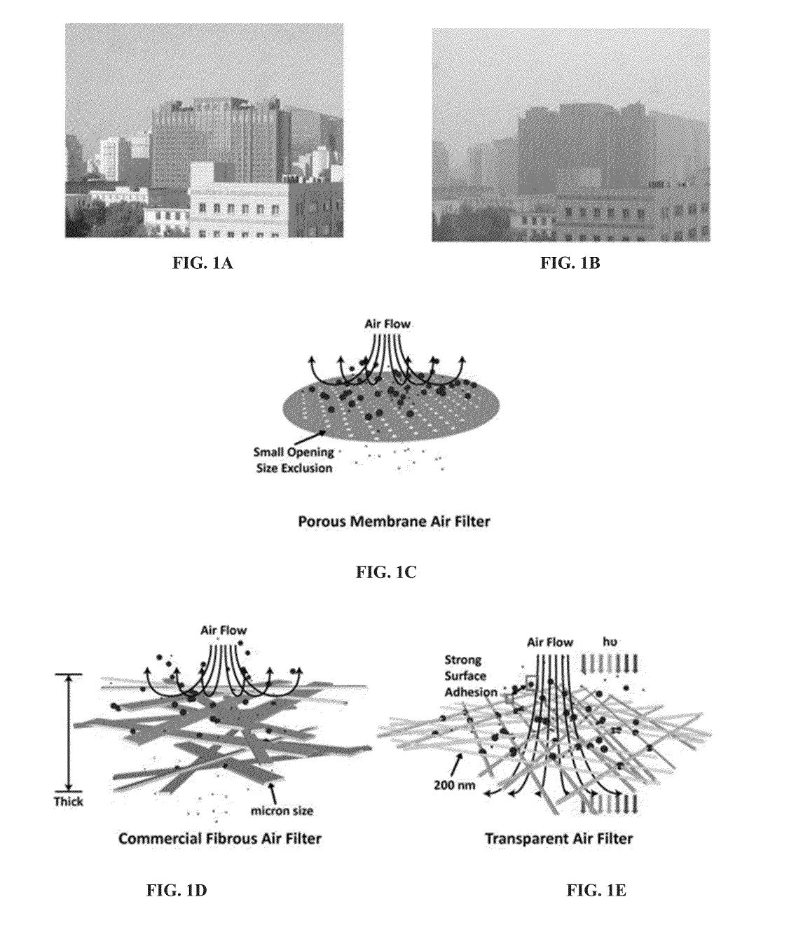

### DETAILED DESCRIPTION

### Introduction

Described here a highly effective air filter with low air flow resistance for removal of PM pollution. Commercial air filters are bulky and have low air flow, which are not compatible with the requirements for a transparent air filter having optical transparency and high air flow. It is demonstrated here that by controlling the surface chemistry of nanofibers to allow strong adhesion between PM and the air filter, by injecting electric charge into nanofibers and also by controlling the microstructure of the air filters to increase the capture possibilities, transparent, high air flow and highly effective air filters can be achieved, which can have ˜90% transparency with >95% removal, ˜60% transparency with >99% removal, and ˜30% transparency with >99.97% removal of PM_{2.5} under extreme hazardous air quality conditions (PM_{2.5} index >300 or PM_{2.5} mass concentration >250 μg/m³). Such a nanofiber filter is not limited to any particular field of use. Its optical transparency is for showing that very thin layer of nanofiber filter can have high efficiency of PM removal. A field test in Beijing showed that an exemplary polyacrylonitrile (PAN) transparent air filter had excellent performance, demonstrating high PM_{2.5} removal efficiencies (98.69%, 99.42%, and 99.88%) at high transmittance (˜77%, ˜54% and ˜40%, respectively). The transparent air filter described herein can be used to solve the serious air pollution issues through indoor air filtration, outdoor personal protection and industrial exhaust filtration.

Air Filter Surface Screening.

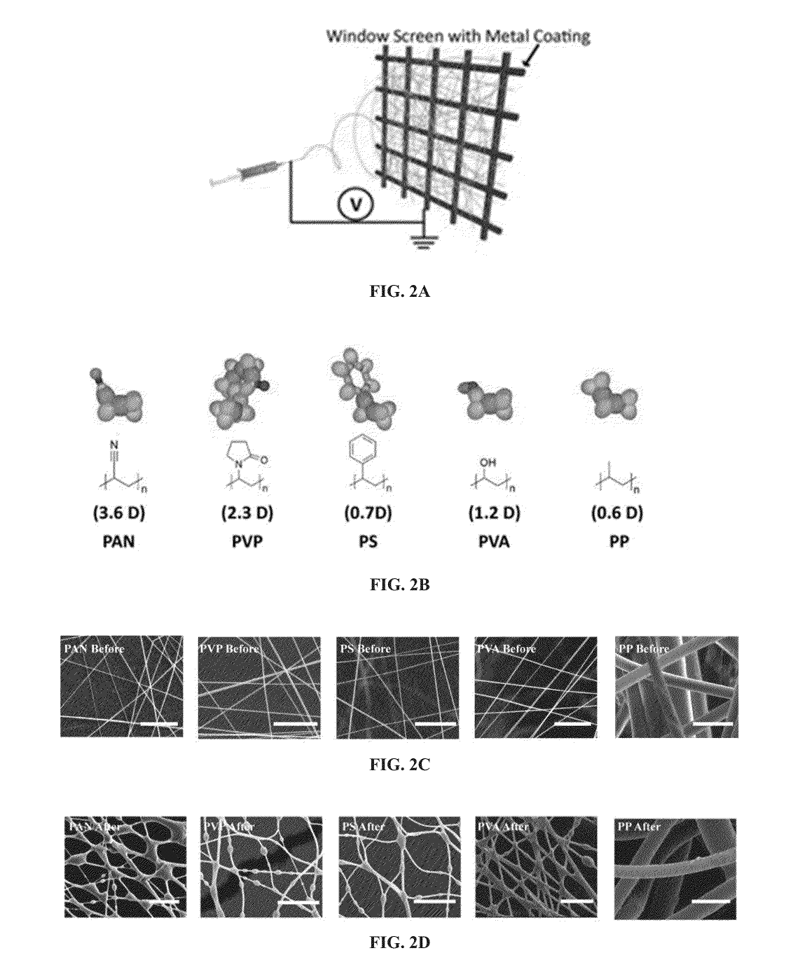

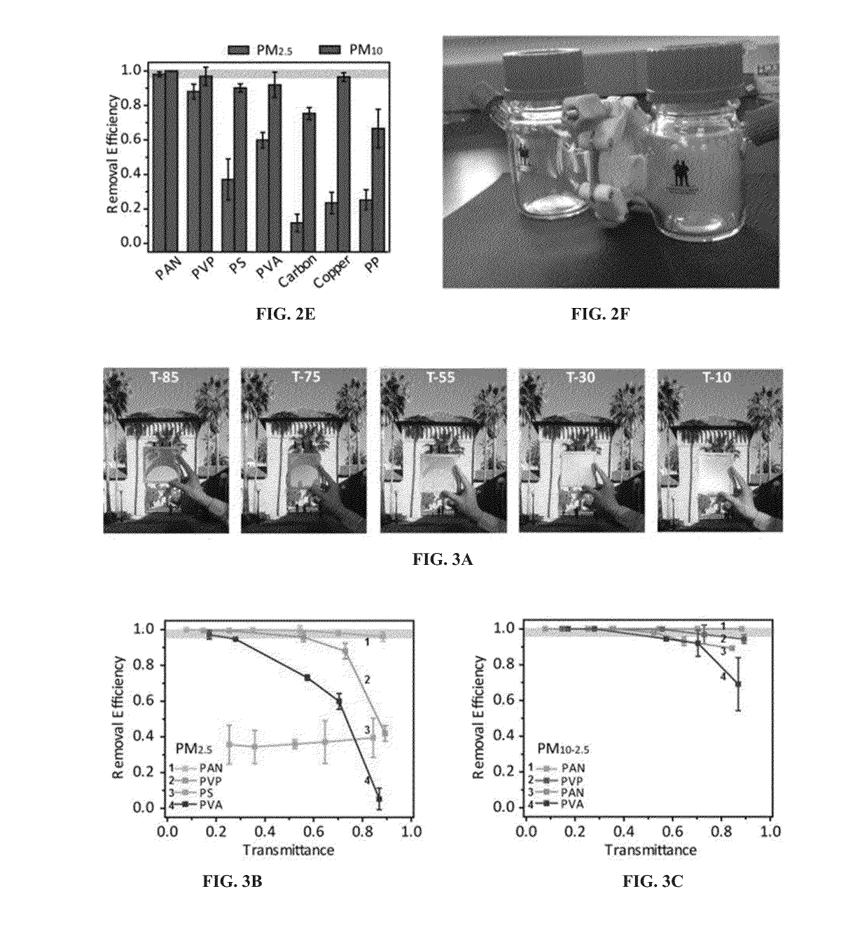

To find effective materials for air filters, different polymers and polymers with other coatings was investigated for PM capture. Electrospinning was used to make polymer nanofibrous air filters (see FIG. 2A). Electrospinning has great advantages in making uniform fibrous filters from diverse polymer solutions with controllable dimensions. This versatility makes electrospinning an ideal tool to produce a transparent nanofiber network. During electrospinning, a high voltage is applied to the tip of a syringe containing a polymer solution; the resulting electrical force pulls the polymer solution into a nanofiber and deposits the fiber onto a grounded collector, which in this experiment was a commercial metal-coated window screen mesh. Due to the electrical field distribution, the electrospun polymer nanofibers lie across the mesh holes and form network for air filtration. This electrospinning method is scalable and with the window screen as a supporting and adhering substrate, the air filter is mechanically robust. Nanofibers with different surface properties are made by changing the functional groups on the polymer side-chains and also by coating different materials using a sputtering method. The chosen polymers are available in large quantity and at low cost, including polyacrylonitrile (PAN), polyvinylpyrrolidone (PVP), polystyrene (PS), polyvinyl alcohol (PVA) and polypropylene (PP). The coating materials are copper and carbon. PP, copper and carbon are all commonly used materials in commercial fibrous or porous membrane air filters. The molecular models and formulas of the different polymers are shown in FIG. 2B. The polarity and hydrophobicity is different between each polymer and the dipole moments are 3.6 D, 2.3 D, 0.7 D, 1.2 D and 0.6 D for the repeating units of PAN, PVP, PS, PVA and PP respectively.

For testing the transparent air filter descried herein, the PM is generated by burning incense. The burning incense contains PM above 45 mg/g burned, and the exhaust smoke contains a variety of pollutant gases, including CO, CO₂, NO₂, SO₂ and also volatile organic compounds, such as benzene, toluene, xylenes, aldehydes and polycyclic aromatic hydrocarbons (PAHs). This complex air exhaust is a model system containing many of the components present in polluted air during hazy days. A scanning electron microscope (SEM) was first used to characterize different fibrous filters before and after filtration. The images are shown in FIGS. 2C, 2D. The as-made nanofiber filters of different polymers had similar morphology with fiber sizes ˜200 nm and similar packing density. Since PP fibers cannot be made by electrospinning, they were peeled off from commercial mask to a transmittance of 70%. The PP thus has a different morphology, with fibers of much larger diameter as compared to the electrospun nanofibers. The SEM images of different filters after the filtration test show that the number and size of PM particles coated on the PAN filter were both larger than that of other polymers. The smoke PM formed a coating layer strongly wrapped around each nanofiber instead of only attaching to the surface of the nanofibers as in the case of inorganic PM (see FIGS. 7A-7B). For the commercial PP air filters, the PM particles captured can hardly be seen.

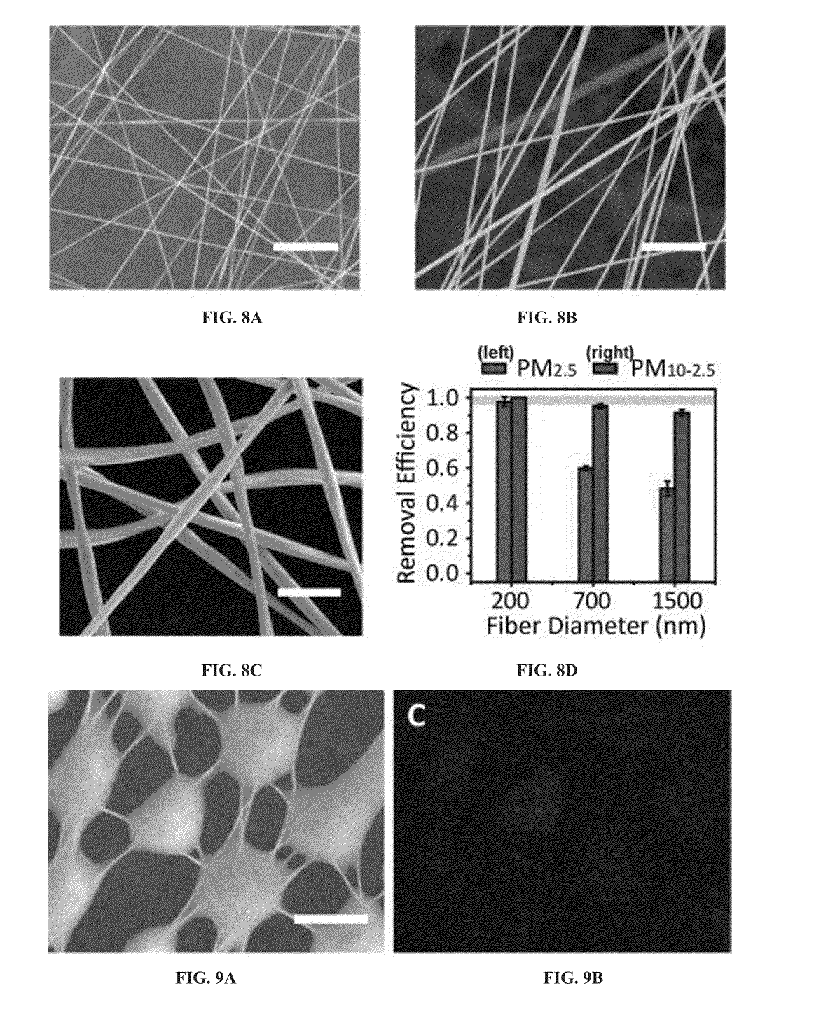

The quantified PM_{2.5} and PM_{10-2.5} removal by different fibrous filters is shown in FIG. 2E. All fibrous filters are at the same transmittance (˜70%). From the efficiency comparison, it is shown that the PAN has the highest removal of both PM_{2.5} and PM_{10-2.5} followed by PVP, PVA, PS, PP, copper, and carbon. The highlighted zone (95%-100%) in FIG. 2E marks the standard for a high efficiency filter and of those tested, only the transparent PAN filter meet this requirement. The removal efficiencies are calculated by comparing the PM particle number concentration with and without air filters. The results showed that the polymer capture efficiencies increase with increasing dipole moment of the polymer repeating units, suggesting that a dipole-dipole or induced-dipole force can greatly enhance the binding of PM to polymer surface and polymers with higher dipole moment would have better removal efficiencies of PM particles. Inorganic PM_{2.5} and PM_{10-2.5} also showed that PAN air filter was very effective in capturing PM particles. The soft PM with larger amounts of carbon and water content tend to be more difficult to capture than rigid inorganic PM since the capture efficiencies of fibrous filters made from the same material are lower in soft PM capture (FIGS. 7A-7B). Besides surface chemistry, the filter's fiber dimension also affects the PM removal efficiency significantly as shown in FIGS. 8A-8D. As the fiber diameter increased from ˜200 nm to ˜1 μm, the removal efficiencies of PAN air filters with the same transmittance of 70% decreased from 97% to 48%. A demonstration of using a transparent filter to block PM pollution was shown in FIG. 2F. In the right bottle, a hazardous level of PM with PM_{2.5} index >300 or PM_{2.5} mass concentration >250 μg/m₃ was generated and a PAN transparent filter with ˜70% transmittance was placed between the PM source and another bottle. As shown in FIG. 2F, the left bottle was still clear and the PM_{2.5} concentration was in a good level marked by the PM_{2.5} index (mass concentration <15 μg/m₃). This demonstration shows the efficacy of the PAN transparent filter.

Evaluation of the PM Removal Efficiency, Optical Transparency and Air Flow of Transparent Air Filters.

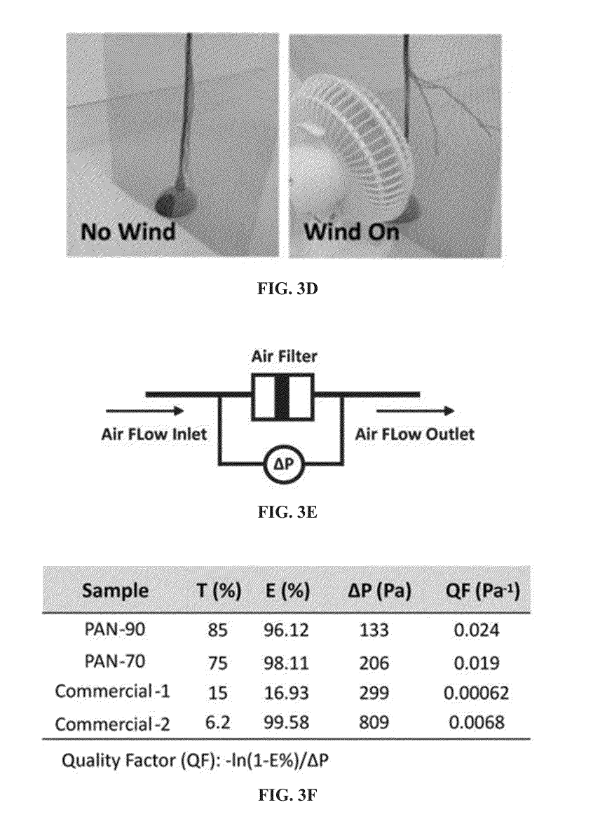

Besides capture efficiency, the other two parameters for a transparent air filter, light transmittance and air flow, were then evaluated. FIG. 3A shows the photographs of the PAN transparent air filters with transmittance of ˜85%, ˜75%, ˜55%, ˜30% and ˜10%. For the air filters with transmittance above 50%, sufficient light can penetrate through and allow lighting from sun and sight-viewing. The PM capture efficiencies of different polymer nanofibrous filters were assessed at different transmittance levels, and the results are shown in FIGS. 3B-3C. By increasing the thickness of the fibrous filter, the PM_{2.5} capture efficiencies of PAN, PVP and PVA filters increased (see FIGS. 2B-2C). For the PAN filter, excellent capture efficiencies were achieved for a variety of optical transmittance levels: >95% removal at ˜90% transparency and >99% removal at ˜60% transmittance for PM_{2.5} capture. A >95% efficiency of PM_{2.5} capture by PVP and PVA filter was achieved at lower transmittance of ˜60% and ˜30%, respectively. However, for PS fibers used in many commercial filters, increasing the filter thickness does not improve the PM_{2.5} capture efficiency by much. The removal efficiency of PM_{10-2.5} particles (see FIG. 3C) are all higher than that of PM_{2.5} in all four polymer air filters and most of the cases the removal efficiencies meet the >95% efficiency standard. PAN showed better capture ability than other polymer filters with similar transmittance.

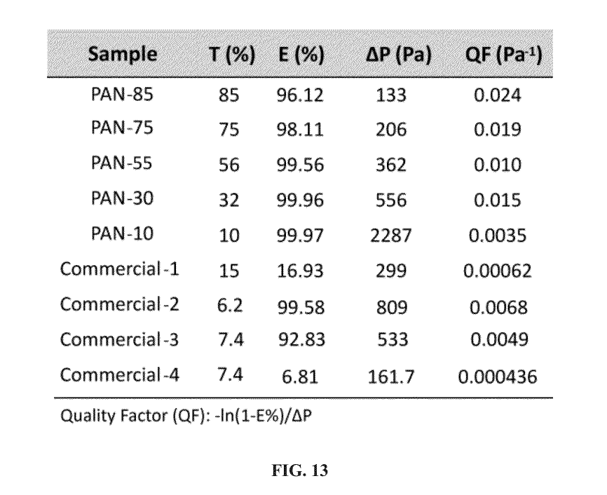

Besides capture efficiency, keeping a high air flow is another parameter to assess the performance of an air filter. All air flow tests were based on PAN air filter. In FIG. 3D, the air penetration through PAN transparent air filters was demonstrated by wind generated by a fan. A PAN transparent air filter with transmittance of ˜90% was placed in front of a bundle of paper tassels hanging on a stick. When wind was blowing from the fan, the paper tassels was blown up with the PAN air filters in front of it which demonstrated great penetration of air through the transparent filter. Quantitative analysis of the air penetration was done by investigating the pressure drop (ΔP) of the transparent PAN filter with different levels of transmittance. FIG. 3E shows the schematic of the pressure drop measurement. The pressure difference across the air filter was measured. It is shown in FIG. 3F that at a face velocity of 0.21 m/s, the pressure drops of 85% and 75% transmittance air filters are only 133 and 206 Pa, respectively. This pressure drop is only <0.2% of atmosphere pressure, which is negligible. These levels of pressure drop are similar to that of a blank window screen without nanofibers (131 Pa). The ΔP increases with the increase of filter thickness or the decrease of transmittance. The overall performance of the air filter considering both efficiency and pressure drop is assessed by quality factor (QF) (see FIG. 3F and FIG. 13). The transparent PAN filter showed higher QF than the four commercial filters (SEM shown in FIGS. 8A-8D) from 2 fold to even orders of magnitudes.

In-Situ Time Evolution Study of PM Capture by PAN Transparent Filter.

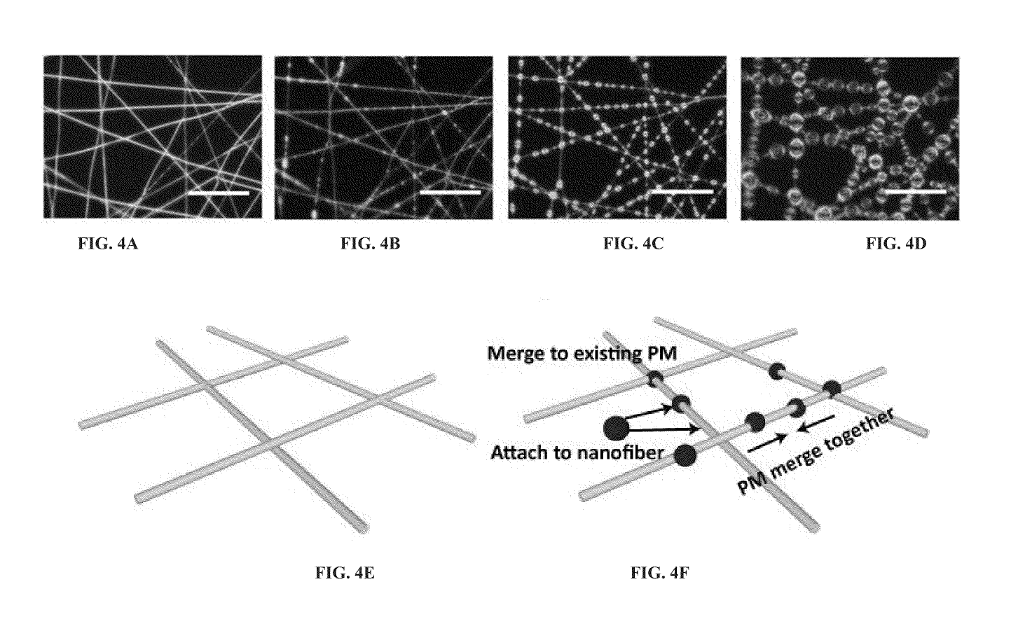

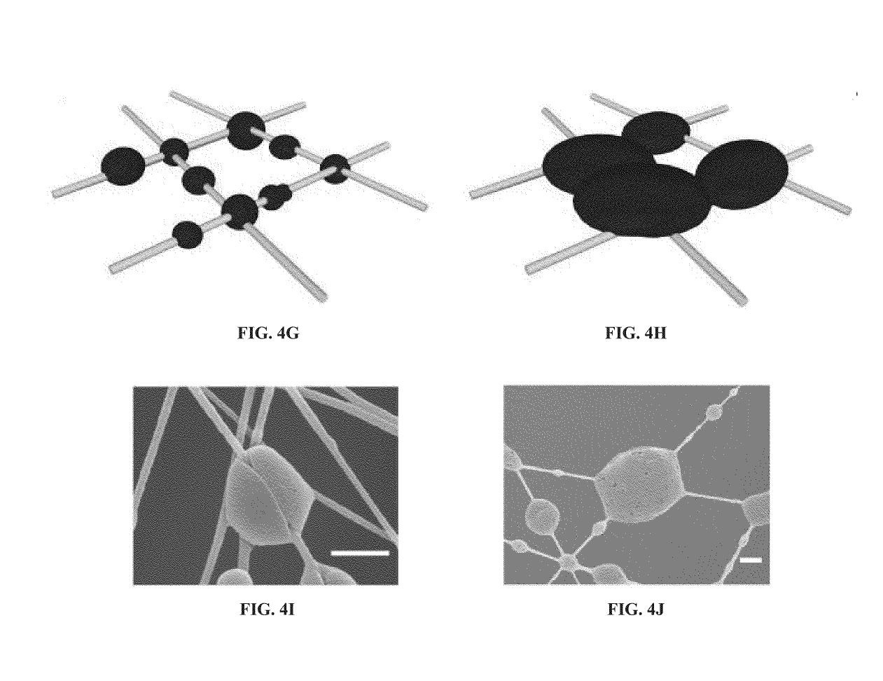

The PM capture process and mechanism was studied by in-situ optical microscope (OM) and SEM using a PAN nanofibrous filter with a fiber diameter of ˜200 nm. The PAN nanofibrous filter was placed under the OM. Continuous flow with high concentration of smoke PM was fed to the fibrous filter. FIG. 4A shows the PAN fiber filter before capturing PM. In FIGS. 4B-4D, the time sequence of PM capture is shown. Schematics explaining the PM capture at different stages are shown in FIGS. 4E-4H. At the initial capture stage (FIGS. 4B and 4F), PM was captured by the PAN nanofibers and bound tightly onto the nanofibers. As more smoke was fed continuously to the filter, more PM particles were attached. The particles were able to move along the PAN nanofibers and aggregate to form larger particles and left behind some empty spaces for new PM particles to attach. In addition, the incoming new PM particles could attach directly to the PM that were already on the PAN nanofibers and merged together (see FIG. 4F). As the capture kept going on, the PAN filters were filled with big aggregated PM particles. The junction of nanofibers had more PM accumulated and formed spherical particles in bigger sizes.

SEM was used to characterize the detailed interaction between PM particles and PAN nanofibers and the images are shown in FIGS. 4I-4J. The general capture mechanism of soft PM particle is that after being in contact with the PAN nanofiber, the PM particle would wrap around the nanofibers tightly (see FIG. 4I), deform and finally reach to a stable spherical shape on the nanofiber. This wrapped around coating indicates that the PM particles favor the surface of PAN nanofibers so that they would like to enlarge their contact areas and bind tightly to ensure an excellent capture performance.

PM Chemical Composition Analysis.

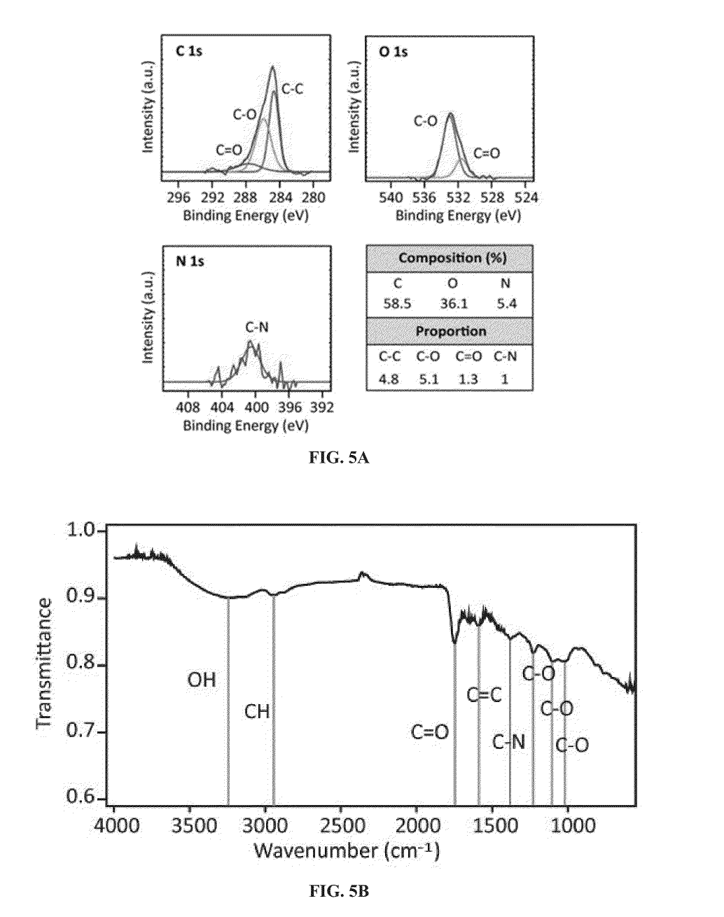

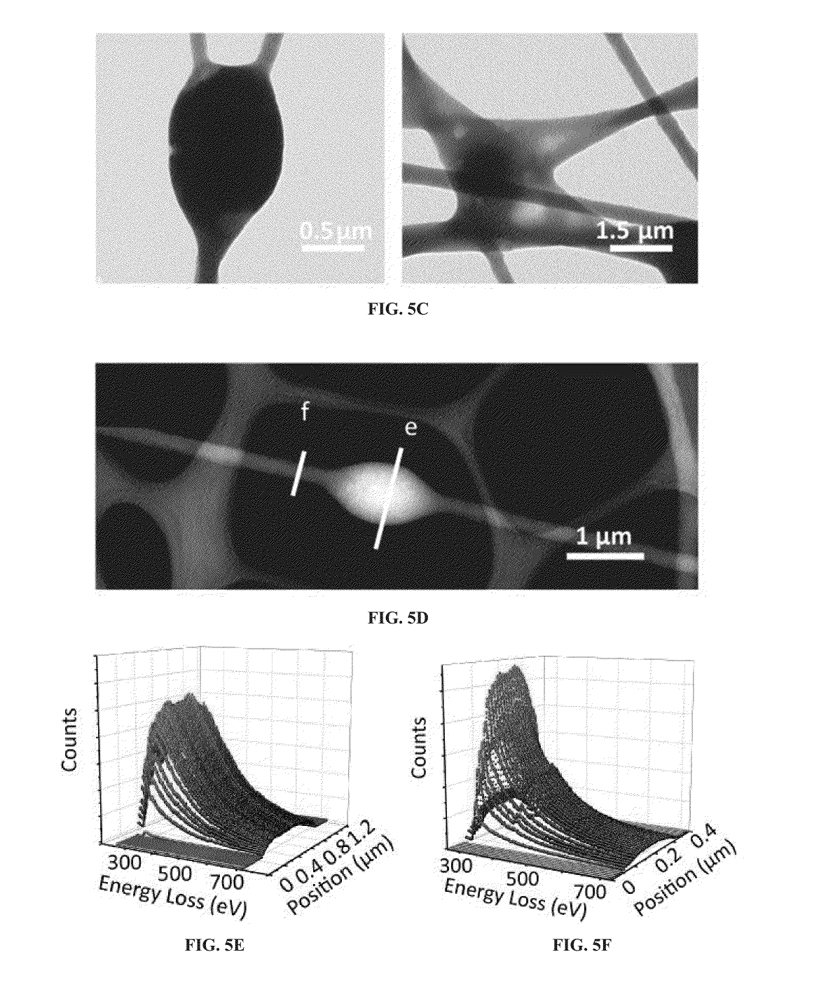

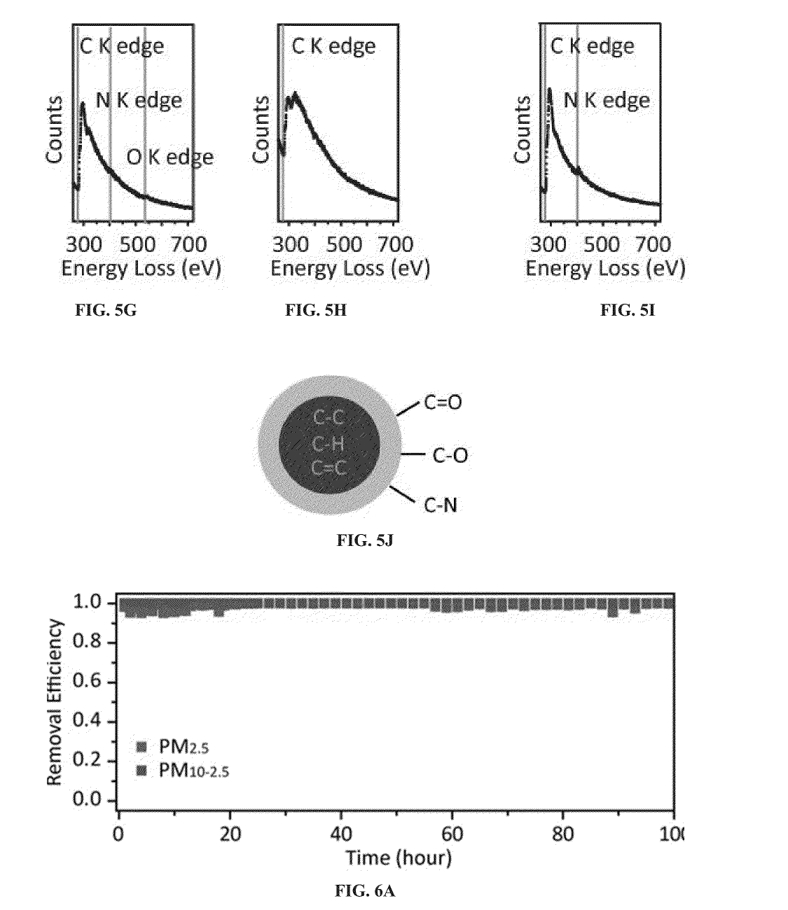

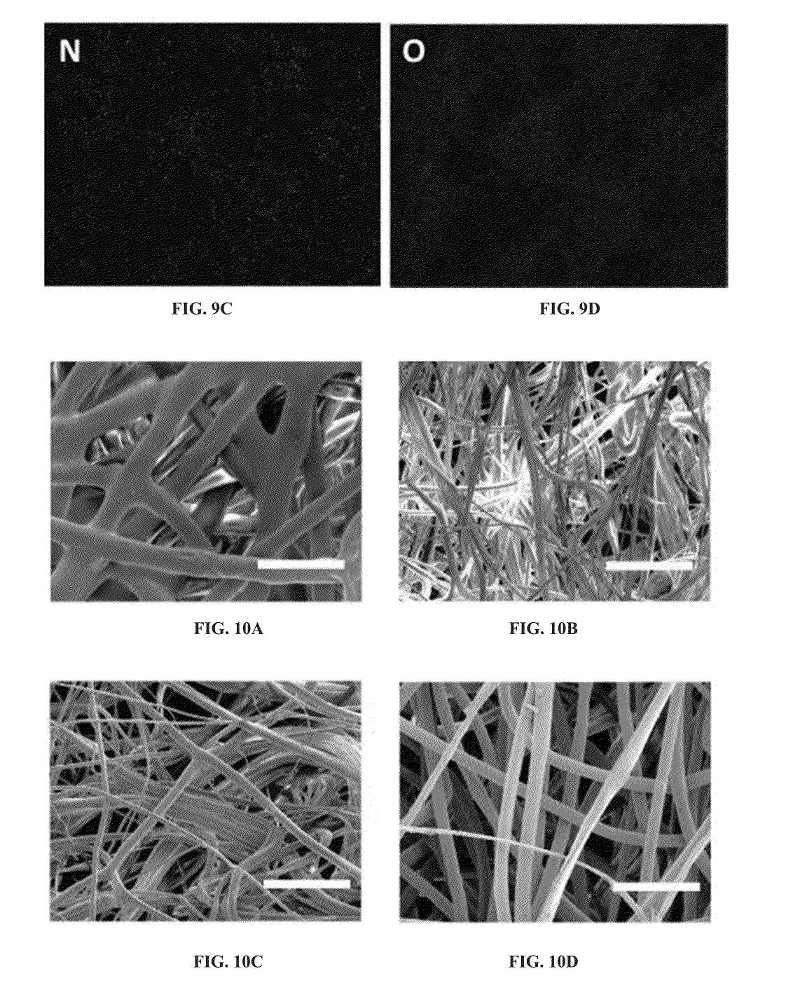

To further explain the performance difference of different fibrous filters in capturing smoke PM, the composition and surface chemistry of smoke PM was investigated. FIG. 5A shows the X-ray photoelectron spectroscopy (XPS) characterization of PM. XPS only detected the surface element composition (˜5 nm in depth) of the smoke PM. It is shown that the C 1s signal comprises three major peaks at 284.7 eV, 285.9 eV and 286.6 eV, corresponding to C—C, C—O and C═O bonds. The O 1s peaks support the results of C 1s peaks and show the present of C—O and C═O at 533.1 eV and 531.9 eV. Besides these elements, a small proportion of N is present on the surface of smoke particle which is shown at the peak of 400.8 eV of N 1s. The overall results show that C, O and N are the three elements present on smoke PM surface and their ratio is 58.5%, 36.1% and 5.4%. The functional groups are C—C, C—O, C═O and C—N with a ratio of 4.8:5.1:1.3:1. The bulk composition of smoke PM was characterized by Fourier transform infrared spectroscopy (FTIR) and the spectra is shown in FIG. 5B. The main peaks are at ˜3311 cm₋₁, 2291 cm₋₁, 1757 cm₋₁, 1643 cm₋₁, 1386 cm₋₁, 1238 cm₋₁, 1118 cm₋₁ and 1076 cm₋₁ which indicated the existence of O—H, C—H, C═O, C═C, C—N and C—O (last three peaks) functional groups. Also, energy-dispersive X-ray spectroscopy (EDX) characterization showed same composition of C, N and O in PM particles (see FIGS. 9A-9D). The XPS, FTIR and EDX analysis show consistent results of the smoke composition which contains mostly organic carbon with functional groups of different polarities such as alkanes, aldehyde and so on. The functional groups of high polarities, such as C—O, C═O and C—N are mainly distributed on the outer surface of the particles. To further demonstrate the functional groups distributions across the PM particle, transmission electron microscopy (TEM) and electron energy loss spectroscopy (EELS) are used to characterize the smoke PM captured on PAN fiber. FIG. 5C shows the morphologies of PM attached to the PAN fibers. The PM particles has a sticky amorphous carbon like morphology with the cores containing some condensed solids while the outer surfaces containing light organic matters. EELS was used to measure the energy loss across the PM attached to PAN fiber (FIGS. 5D and 5E) and bare PAN fiber (FIGS. 5D and 5F). The result shows that at the PM particle, the chemical contents changes with position. By scanning the beam from one end of the PM to the other end, the peaks of the C K edge (284 eV), the N K edge (401 eV) and the O K edge (532 eV) were firstly shown at the outer surface of the PM (see FIG. 5G). As the beam moved to the center of the PM, the N K edge and O K edge signals diminished and only the C signal was present (shown in FIG. 5H). At last, as the position moved to the outer surface again, the N K edge (401 eV) and O K edge (532 eV) peaks showed up again. As control, the EELS signal of the PAN fiber showed the same signal all across the whole fiber with C K edge (284 eV) and N K edge (401 eV) which matches the chemical composition of the PAN polymer (see FIG. 5I). This indicates again that the polar functional groups which contain O and N (C—O, C═O and C—N) are mostly present on the outer surface of PM accompanied by some nonpolar functional group such as alkanes (see FIG. 4J). This is consistent with the result that polymer air filters with higher dipole moments have higher PM capture efficiencies. Because the polar functional groups such as C—O, C═O and C—N were present at the outer surface of the PM particles, polymers with higher dipole moment can have stronger dipole-dipole and induced-dipole intermolecular forces so that the PM capture efficiency is higher.

PAN Transparent Air Filter Long Term Performance.

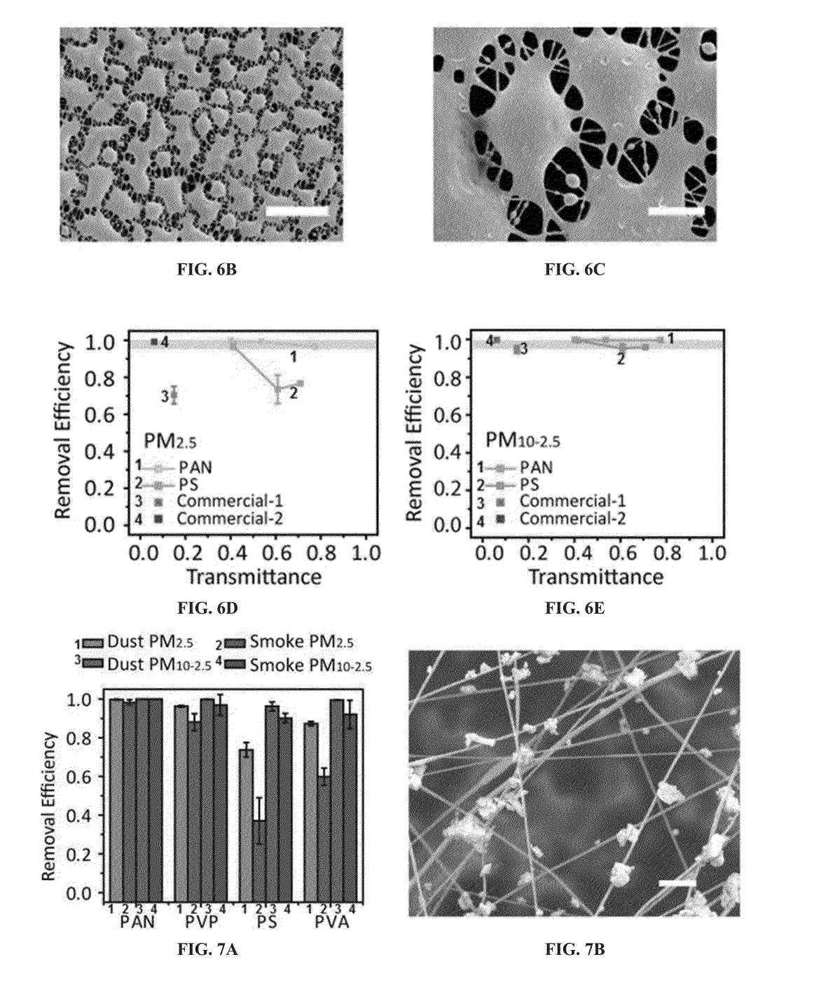

The long term performance of the transparent filter was evaluated using a PAN filter with a transmittance of ˜75% under the condition of hazardous level equivalent to PM_{2.5} index >300 and a mild wind condition (<1 miles per hour). The performance is shown in FIG. 6A. After 100 hours, the PAN filter still maintained a high PM_{2.5} and PM_{10-2.5} removal efficiency of 95-100% and 100%, respectively and the pressure drop only increased slightly from ˜2 Pa to ˜5 Pa. The SEM images in FIGS. 6B, 6C showed the morphologies of PAN nanofibrous filter after 100 hours test. The PM particles captured were aggregated and formed domains of very large particles of 20-50 μm. No detachment of PM was noticed after using clean air to blow through the used PAN filter by measuring the mass loss (within 0.006% of error bar). A separate PM adsorption test has shown that the PAN transparent filter achieved a capture of PM pollutants 10 times of the mass to the filter's self-weight. This 10× capability implies that the lifetime of a transparent filter with transmittance of ˜75% was expected to be above 300 hours under hazardous PM level (PM index >300).

Performance of the Transparent Air Filters in a Field Test (Beijing, China).

In order to study the efficacy of the filters in a real polluted air environment, a field test was carried out on Jul. 3, 2014 in Beijing, China. The PM_{2.5} was at a hazardous level equivalent to a PM_{2.5} index >300. The results are shown in FIGS. 6D, 6E. PAN filters with transmittance ˜77%, ˜54%, ˜40% achieved PM_{2.5} and PM_{10-2.5} removal efficiencies of 98.69%, 99.42%, 99.88% and 99.73%, 99.76%, 99.92%, respectively. For comparison, a PS filter, which showed lower removal of smoke PM, consistently showed lower removal of PM_{2.5} and PM_{10-2.5} in the field test, of 76.61%, 73.50%, 96.76% and 95.91%, 95.17%, 99.44% at transmittance of 71%, 61%, 41%, respectively. Also, commercial masks commercial-1 and commercial-2 with PP fibers (images shown in FIGS. 10A-10D) were tested for comparison. Commercial-1 showed much lower PM_{2.5} and PM_{10-2.5} removal of 70.40% and 94.66%. Commercial-2 showed comparable removal efficiencies of PM_{2.5} (99.13%) and PM_{10-2.5} (99.78%) although it is essentially not transparent (transmittance 6%). Hence, PAN showed great performance as a transparent filter.

Performance of PAN Transparent Air Filter Under Different Humidity and Wind Force Conditions.

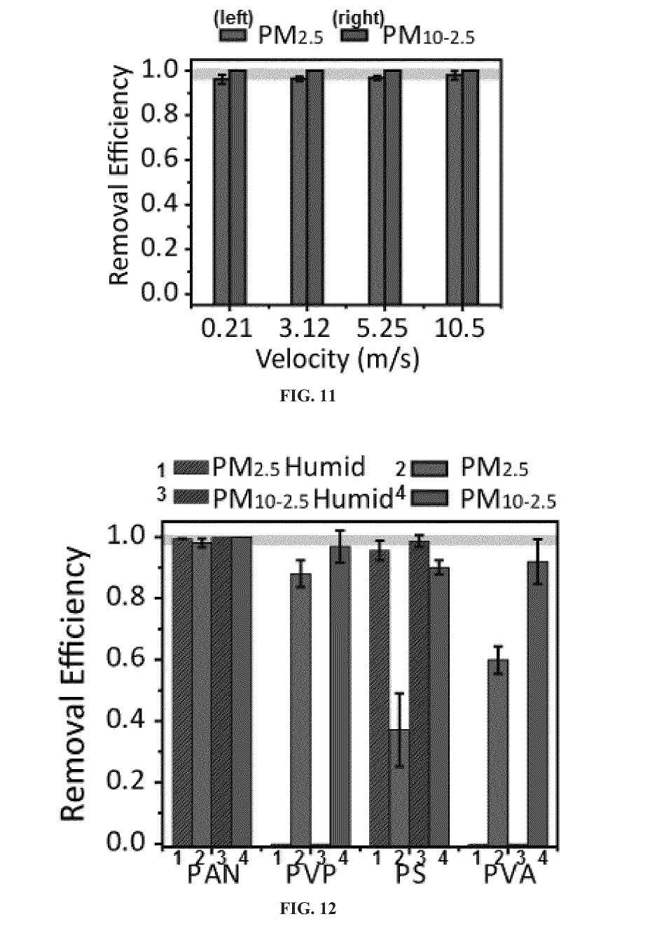

Based on the real weather situation, wind force and humidity were also taken into consideration and the results are shown in FIG. 11 and FIG. 12. The PAN fibrous filter with transmittance of ˜73% was tested at different wind force representing calm (0.21 m/s), light breeze (3.12 m/s), gentle breeze (5.25 m/s) and fresh wind (10.5 m/s) conditions. The removal efficiencies under all cases were >96% and showed an increasing trend of removal efficiency to wind velocity which could be due to the increase of PM particle rejection. This is consistent with other studies. For PM capture under extreme humid conditions, the results showed that humidity helps PAN and PS with transmittance of ˜70% to achieve better PM capture, especially for PS which increased from 37% to 95%. This is because the ambient water content increased the capillary force between the PM particles and PS nanofibers during PM attachment. However, for PVP and PVA, because of their solubility in water, under extreme humid conditions, the filters were damaged significantly resulting in no detectable removal. In humid condition, PAN transparent filters showed great performance.

In conclusion, it was demonstrated that electrospun PAN nanofibers can be highly effective transparent PM filters because of its small fiber diameter and surface chemistry. Such nanofibrous filters can shut off PM from entering the indoor environment, maintain natural ventilation and preserving the optical transparency when installed on windows. An electrospun PAN transparent air filter with a transmittance of ˜75% can be used under hazardous PM_{2.5} level for as long as 100 hours with efficiency maintained at 95-100%. This high particle removal efficiency has also been proven by a field test in Beijing, showing the practical applicability of the transparent filters. It is believed that the transparent air filter described herein can be used as a stand-alone device or incorporated with existing masks or HEPA filters to achieve a healthier indoor living environment.

Nanofibrous Air Filters with High Temperature Stability for Efficient PM_{2.5} Removal from Pollution Sources.

Particulate matter (PM) pollution has recently become a serious environmental problem in many countries. The direct removal of PM, especially PM_{2.5}, from its sources is of great significance for the reduction of PM pollution. However, most of the PM sources are of high temperature up to 300° C. in the exhaust, which causes challenges for PM_{2.5} removal with existing technologies. Described here are high-efficiency air filters for the high temperature PM_{2.5} removal. The air filters are made of polyimide (PI) nanofibers by electrospinning. For a PI filter with 50% light transparency (only 30˜60 μm thick), >99.50% PM_{2.5} removal efficiency was achieved. The PI nanofibrous air filters exhibited high thermal stability and the PM_{2.5} removal efficiency kept almost unchanged for temperature ranging from 25° C. to 370° C. In addition, the PI filters had high air flux with very low pressure drop. Long-term test showed that the PI nanofibrous air filter could continuously work for more than 120 hours with high PM_{2.5} removal efficiency under extreme hazardous air-quality conditions (PM_{2.5} index>300). A field test showed that the polyimide air filters could effectively remove >99.5% of PM particles across all sizes from car exhaust at high temperature.

High-Efficiency PI Air Filter Fabrication.

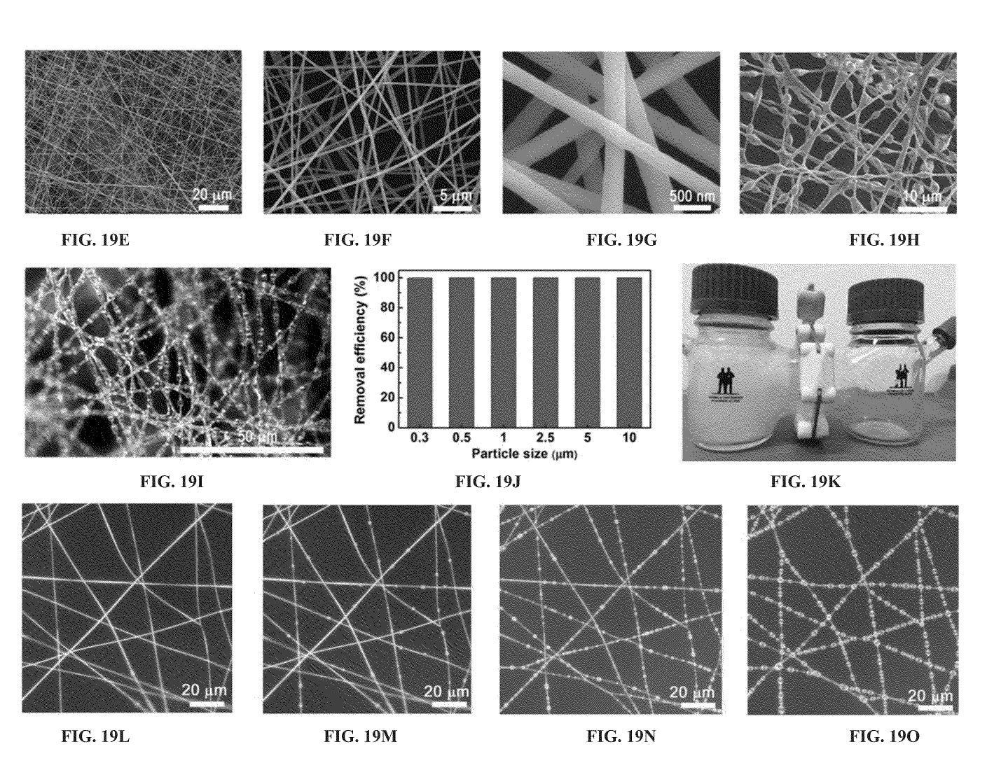

PI was chosen as the exemplary high temperature air filter material because of its excellent thermal stability at high temperatures. PI is a polymer of imide monomers and is known for thermal stability, good chemical resistance, as well as excellent mechanical properties. However, it is not yet known about their capability to remove PM in the air at high temperature. It is believed that polar functional groups are suitable to bind with PM and that PI has the right polar group for this purpose. There are various types of PIs in terms of molecular structures. A general molecular structure of PI is shown in FIG. 19A. For this type of PI molecular, its dipole moment is 6.16 D.

PI nanofibrous air filters were fabricated using electrospinning of PI-dimethylformamide solution. Electrospinning is a versatile processing technique of preparing uniform nanofibrous filters from diverse polymer solutions with controllable dimensions (FIG. 19B). For the synthesis of uniform PI nanofibers, it is desirable to search for a suitable solution concentration, a suitable distance and voltage between the syringe tip and the grounded fiber collector. The collectors used here were copper meshes. By changing the solution concentration and the applied voltage, the diameter of PI nanofibers can be tuned accordingly. At a given working voltage and distance between the syringe tip and the collector, the optical transparency and thickness of PI nanofibrous air filters primarily depends on the electrospinning time. FIG. 19C shows a photo of typical transparent PI air filter fabricated by electrospinning. As shown by the optical microscope (OM) and scanning electron microscope (SEM) images in FIGS. 19D-19F, the as-made PI nanofibers were uniformly distributed on the mesh substrates. The holes are much larger than the fiber diameters, allowing the air flow with little resistance. It was found that the fiber dimensions affect the PM capture efficiency. The fibers with small diameters have a higher available specific surface area than those with large diameters. The smaller the fiber diameter is, the higher the PM capture efficiency is. The diameter of PI nanofibers fabricated here was chosen to be ˜200 nm (FIG. 19G).

The PM particles used in this study were generated by burning incenses, which is a good model system for the air filtration as it contains a wide size distribution of particles and many of the components present in polluted air during hazy days, such as CO, CO₂, NO₂, SO₂ and also volatile organic compounds such as benzene, toluene, xylenes, aldehydes, polycyclic aromatic hydrocarbons, etc. As shown in FIGS. 19H and 19I, the PI nanofibers were coated with many PM particles after filtration. The particles formed a coating layer strongly attached to the surface of nanofibers. FIG. 19J shows the PM removal efficiency of a PI filter with optical transmittance of 50% (the thickness is about 30˜60 μm) at room temperature. Here the optical transmittance was used to indicate the small thickness of the filters which correlates with the capability of high air flow. It has very high PM removal efficiency for particles with different sizes. For example, despite the small thickness of the filters, the PM removal efficiency for particles with sizes of 0.3 μm is as high as 99.98%, reaching the standard of high-efficiency particulate air (HEPA) filters defined as filters with filtration efficiency >99.97% for 0.3 μm airborne particles.

FIG. 19K shows a demonstration of using PI air filter to block high-concentration PM pollution. The left bottle contained a hazardous level of PM with PM_{2.5} concentration higher than 50 μg/m³ and the PI filter with optical transmittance of 65% was placed between the two bottles. The PI filters successfully blocked the PM from moving to the right bottle. Even after a long time (about one hour), the right bottle was still very clear and the PM_{2.5} concentration remained at a low level (<20 μg/m³, less than 4% of the left side bottle.).

The PM capture process and mechanism of the PI nanofibers were also studied by in situ OM imaging. As shown in FIGS. 19L-19O, with the continuous flow of high concentration smoke PM to PI filters, PM particles were captured by the PI nanofibers and attached tightly on them. With the continuous feeding of smoke PM, more PM particles were attached. In the meanwhile, small particles gradually merged into larger ones. As shown by FIG. 19H, compared with the single PI nanofibers, more PM particles merged together around the junctions of the nanofibers and formed even larger ones.

High Temperature PM Removal Performance of PI Air Filters.

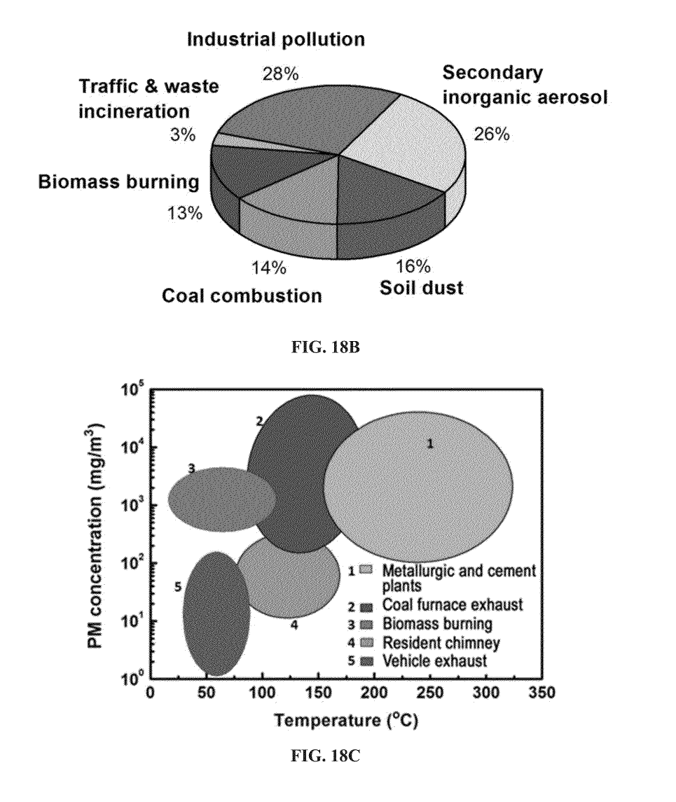

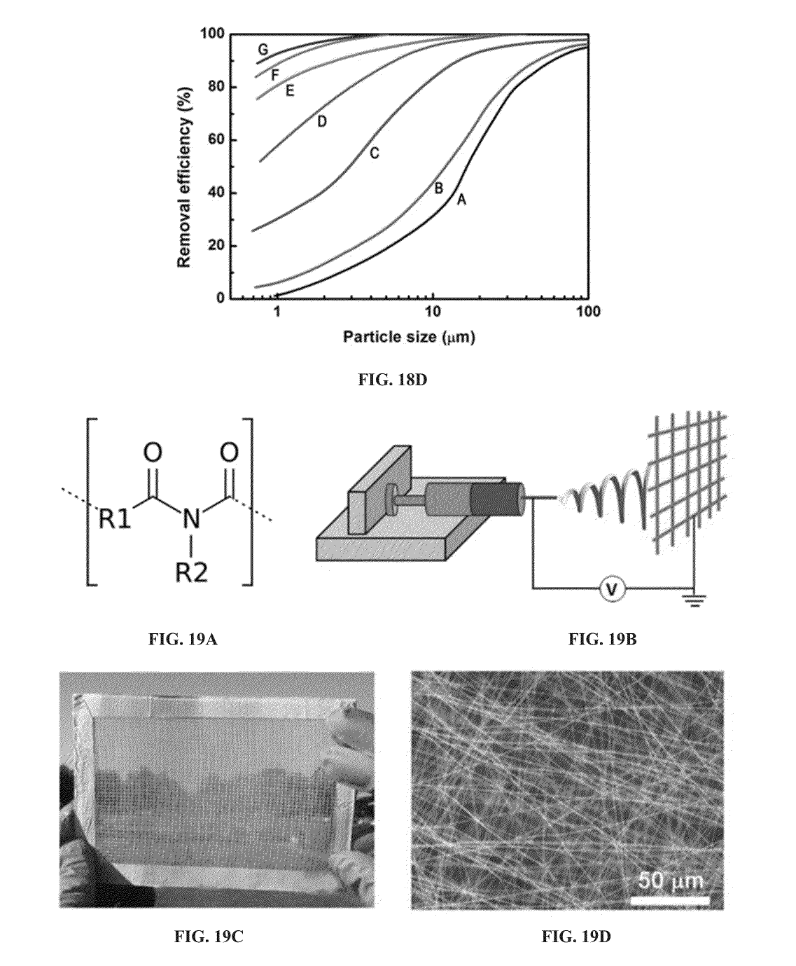

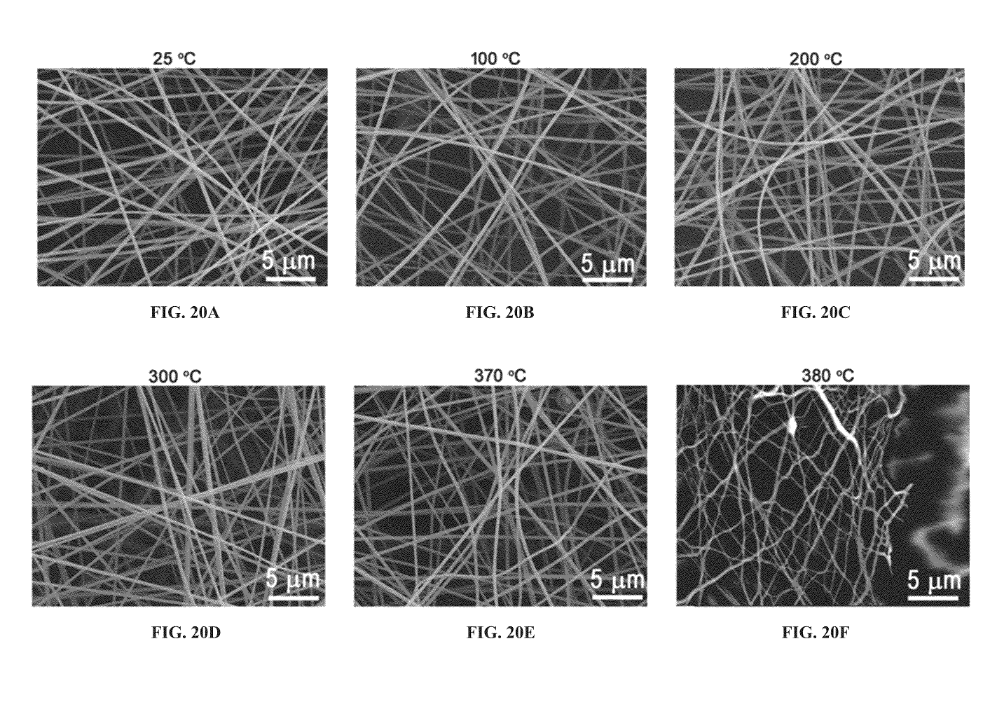

The thermal stability of air filters affects their filtration performance at high temperature. Before testing the high temperature performance of PI nanofibrous air filters, their thermal stability was checked first. The PI nanofibers were placed in a box furnace set with different temperature. Each sample was kept for one hour at each temperature. As shown by FIGS. 20A-20E, when the temperature increased from 25° C. to 370° C., both the diameter and the morphology of the PI nanofibers kept unchanged, showing their high thermal stability. Only when the temperature increased to 380° C., the structure of PI nanofibers began to break down. A big hole appeared in the PI filters (FIG. 20F). The PI nanofibers had evident deformations and most of them distorted. The diameter of PI nanofibers became smaller and some of them even fractured. As shown in FIG. 18C, the temperature of most exhaust gases is lower than 300° C., so the PI nanofibers would be expected to be stable when used for removing PM particles from these exhaust gases.

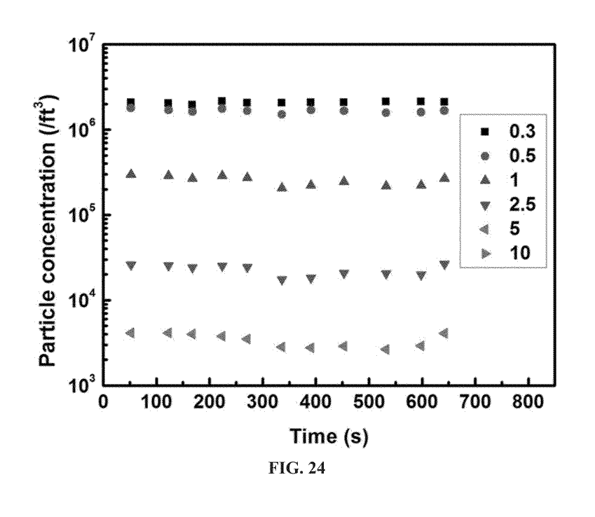

To test the PM removal performance of the as-made PI air filters at high temperature, a special testing device was designed shown as FIG. 20G. A PI filter was placed inside a furnace and connected with the filtration performance testing system. A PM particle counter was used to measure the particle number concentration. The PM used in this study was generated by burning incenses, which contained particles of all sizes, from <0.3 μm to >10 μm, and the particle number concentration of each size kept relatively stable during the testing period (see FIG. 24). The removal efficiencies were calculated by comparing the PM particle number concentration with and without PI filters.

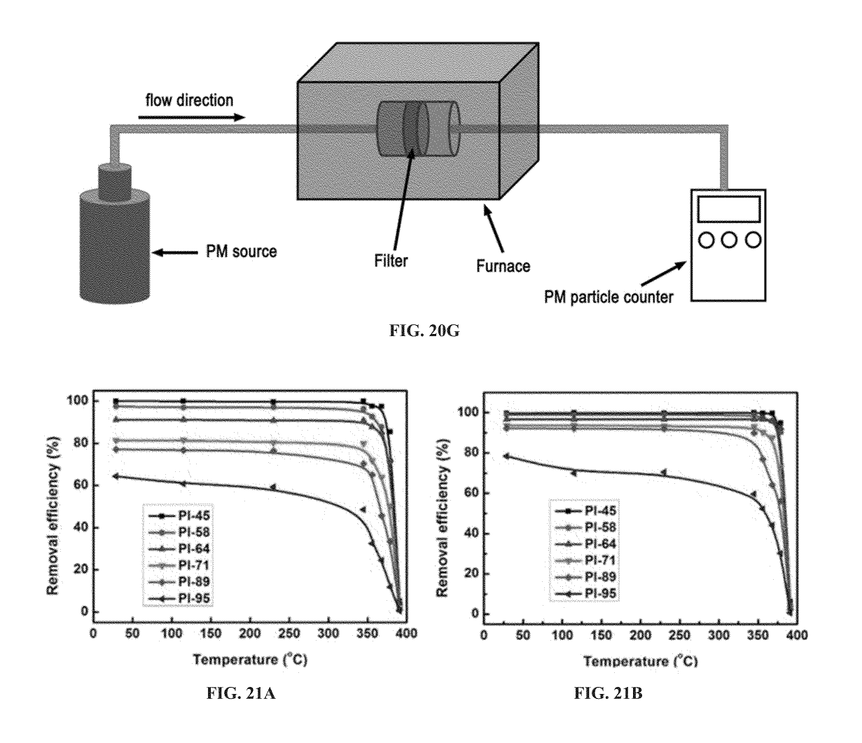

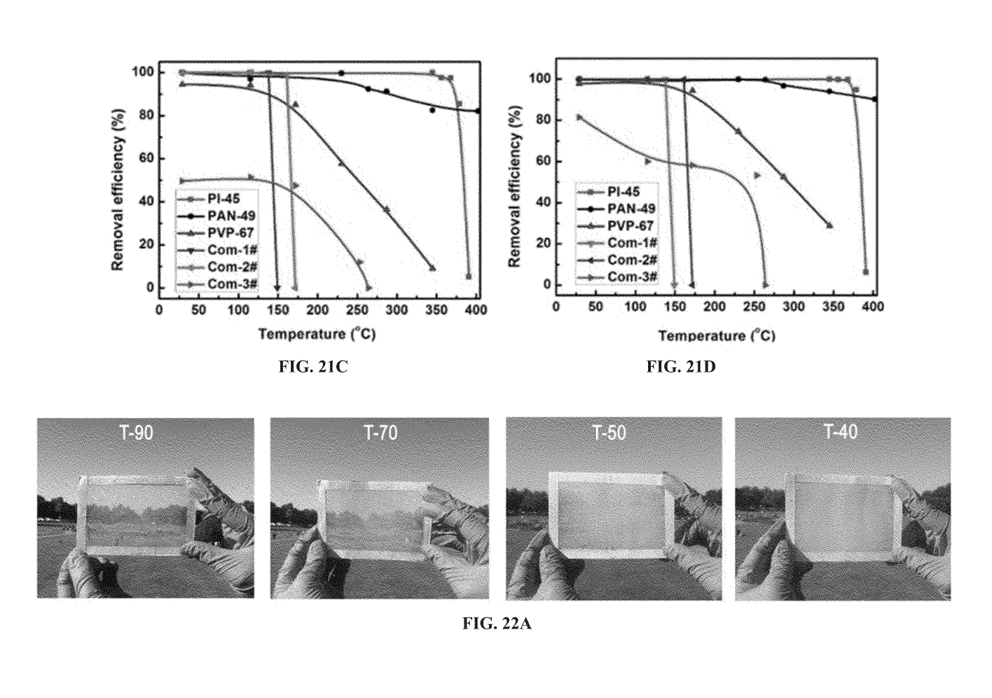

The PM removal efficiency of PI filters was systematically studied with different optical transparency at different temperatures. As shown in FIGS. 21A (for PM_{2.5} removal) and 21B (for PM_{10-2.5} removal), for filters with a wide range of optical transmittance, the PI nanofibrous filters show excellent thermal stability and their filtration performance kept almost unchanged at temperature below 350° C. For PI filters with optical transmittance of about 60%, the PM_{2.5} removal efficiency was higher than 95%, reaching the standard of high efficiency filters. For PI filters with optical transmittance of about 45%, the PM_{2.5} removal efficiency was higher than 99.98%, reaching the standard of HEPA filters defined as filters with filtration efficiency >99.97% for 0.3 μm airborne particles. With the temperature increase, they were stable and their filtration performance kept unchanged. Only when the temperature was higher than 350° C., the structure of PI filters began to change and the PM removal efficiency began to decrease. When the temperature reached 390° C., the PI filters were seriously damaged and the PM removal efficiency almost became zero.

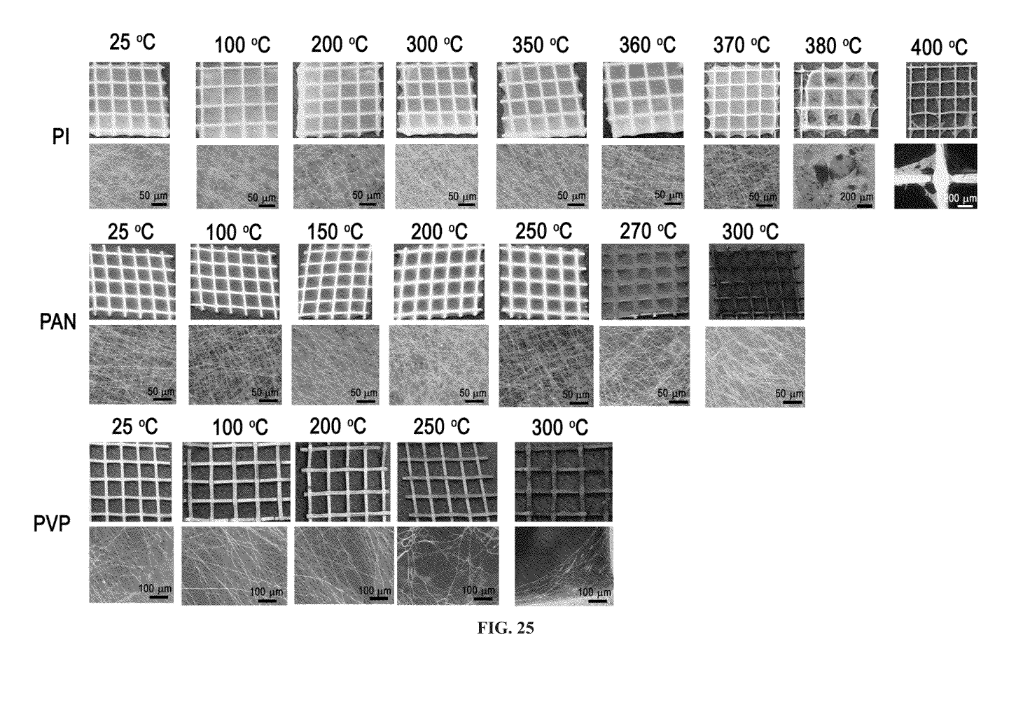

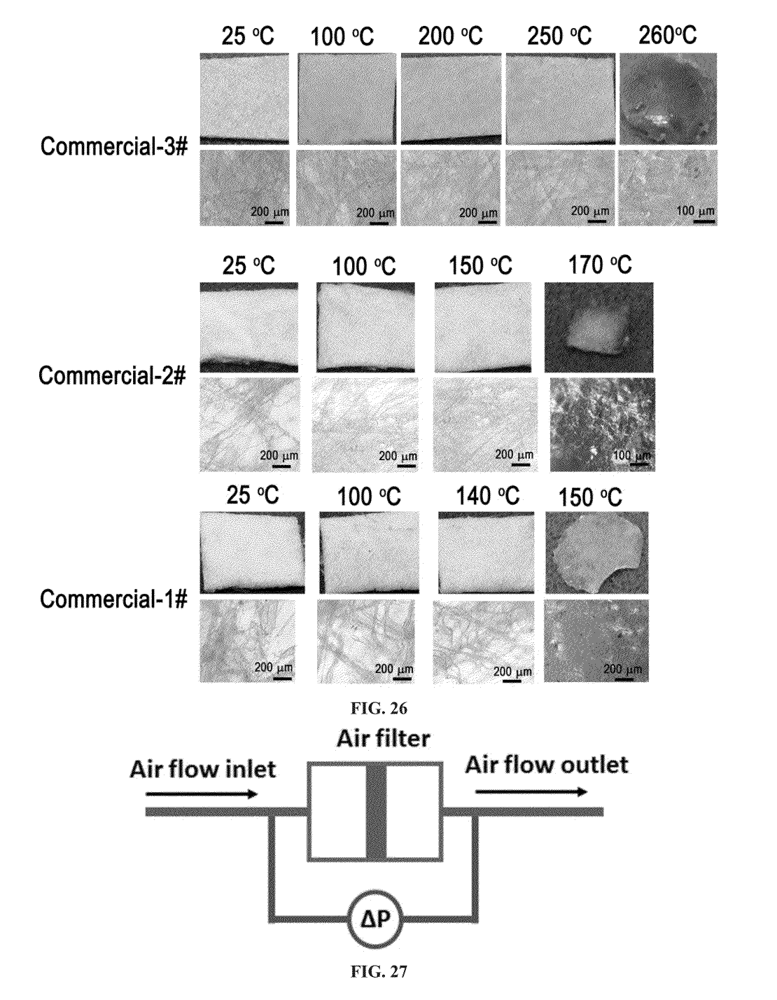

To obtain a better comparison, air filters made of other polymers were also tested, such as polyacrylonitrile (PAN), polyvinylpyrrolidone (PVP) and three kinds of commercial air filters. The PAN and PVP also had diameters of ca. 200 nm. As shown by FIGS. 21C and 21D, it is evident that among the six different kinds of air filters, the PI filters exhibited the best filtration performance at high temperature. For PI filters with optical transmittance lower than 90%, both the PM_{10-2.5} and PM_{2.5} removal efficiency kept almost unchanged at the temperature range of 25˜350° C. Compared with PI, the PAN filters also have high PM removal efficiency at room temperature. However, when the temperature increased to 230° C., the PM removal efficiency of PAN filters gradually decreased. The reason is that PAN would be thermally oxidized in air to form an oxidized PAN fiber when temperature is higher than 230° C. (FIG. 25). The surface chemistry of PAN has a large change after oxidation, which will directly influence the PM removal efficiency of PAN filters. As for the PVP filters, their filtration performance has a decrease when the temperature is higher than 150° C. For the three kinds of commercial filters, their thermal stability is even worse. For example, when the temperature is higher than 150° C., the Com-1# filters will completely melt. The Com-2# filter has a similar phenomenon when the temperature increases to 170° C. The Com-3# filter has a poor filtration performance even at room temperature. When the temperature increased to 200° C., the Com-3# filter gradually melts. From the above comparison, the PI nanofibrous filters have the best PM removal performance and the best thermal stability.

Pressure Drop of PI Filters Compared with Commercial Filters.

In addition to the PM removal efficiency, another desirable parameter is the air flux with low pressure drop. It was reported that energy consumption is directly proportional to the pressure drop over the filters and normally accounts for 70% of the total life cycle cost of air filters. In the average commercial building, 50% of the energy bill is for the HVAC (Heating, Ventilation and Air Conditioning) system and 30% of that is directly related to the air filtration. Therefore, the low pressure drop of filters would save a lot of energy and cost during their applications.

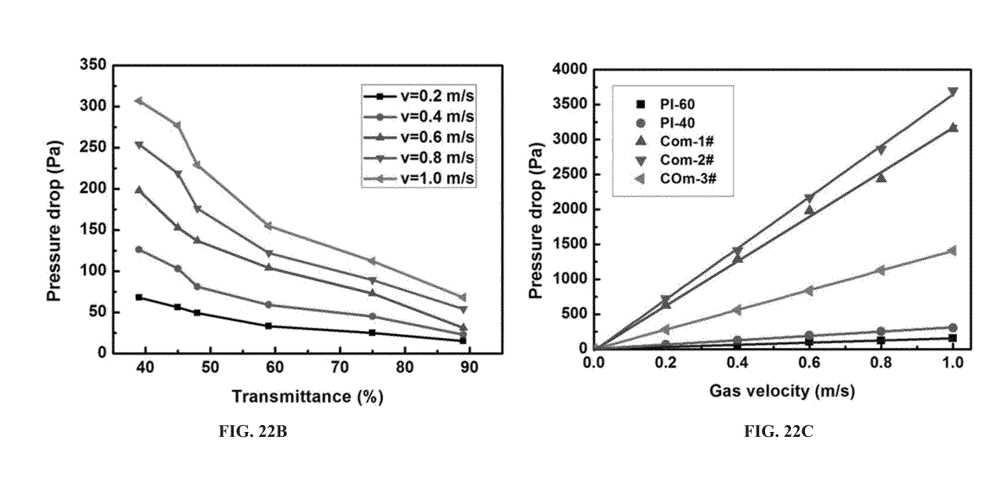

There is usually a conflict between the two desirable filtration parameters: removal efficiency and high air flux with low pressure drop. A good filter is expected to show both a high filtration efficiency and a low pressure drop. Optical transmittance is a direct observation of the thickness of filters, correlated with the air flux. As shown in FIG. 22A, there are four PI nanofibrous air filters with different optical transmittance. Here the pressure drop of PI nanofiber filters with different optical transmittance were compare under a variety of air flow rate (FIG. 22B). FIG. 27 shows a schematic of the pressure drop measurement. As shown in FIG. 22B, with the decrease of optical transmittance, the pressure drop of PI air filters increases. However, even for the thickest PI filters with the lowest optical transmittance at 40%, the pressure drop is only ˜70 Pa at a gas velocity of 0.2 m/s. Even at a gas velocity of 1 m/s, the pressure drop for PI filters with optical transmittance of 40% is only about ˜300 Pa. In comparison, the three different commercial air filters have much higher pressure drop than PI air filters (FIG. 22C). Although Com-1# and Com-2# commercial air filter have high PM removal efficiency (FIGS. 21C and 21D), their pressure drop is too large to allow for a high air flow (FIG. 22C). For example, at the flow rate of 0.6 m/s, PI-40 (40% optical transmittance) with similarly high PM removal efficiency have small pressure drop of ˜200 while Com-1# and Com-2# have a pressure drop about an order of magnitude higher at 2000 and 2200 Pa, respectively. The overall performance of the air filters considering both efficiency and pressure drop is assessed by a quality factor (QF), which is defined as QF=−ln(1−E)/ΔP, where E is PM removal efficiency and ΔP is the pressure drop of the filters. The higher the QF, the better the filter is. An overall performance comparison of different air filters is summarized in Table 1, which clearly shows that PI filters have the best air filtration performance considering PM removal efficiency, pressure drop, the quality factor and the highest stable-working temperature.

TABLE 1
Performance summary of different air filters

| Sample | T (%) | E (%) | ΔP (Pa) | QF (Pa⁻¹) | t (° C.) |
|---|---|---|---|---|---|
| PI-40 | 40 | 99.97 | 73 | 0.1072 | 370 |
| PI-60 | 60 | 97.02 | 45 | 0.078 | 370 |
| PAN-45 | 49 | 99.97 | 80 | 0.1014 | 230 |
| PVP-67 | 67 | 94.43 | 71 | 0.0407 | 150 |
| Com-1# | 7.3 | 99.91 | 629 | 0.0112 | 140 |
| Com-2# | 6.5 | 99.87 | 723 | 0.0092 | 160 |
| Com-3# | 13 | 49.66 | 281 | 0.0024 | 170 |

Note:
T: optical transmittance; E: PM_{2.5} removal efficiency; ΔP: pressure drop; QF: quality factor; t: highest stable-working temperature. QF = −ln (1 − E)/ΔP.

Long-Term and Field-Test Performance of PI Nanofibrous Air Filters.

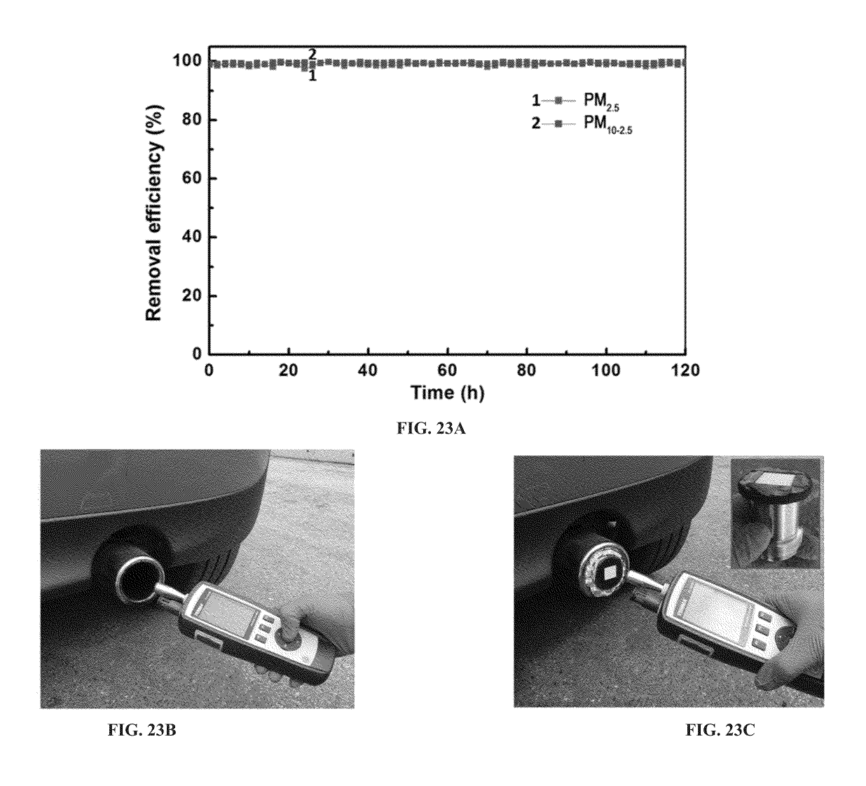

The long-term and field-test performance is desirable for the practical application of PI air filters in real environments. The long-term performance of the PI nanofibrous air filters was evaluated by using a PI filter with optical transmittance of 55% with temperature of 200° C. under the condition of hazardous level equivalent to the PM_{2.5} index >300 and mild wind condition (the wind speed is about 0.2 m/s). The long-term PM particle removal performance of PI filters is shown in FIG. 23A. After continuously working for 120 hours at 200° C., the PI air filter still maintained a high PM removal efficiency. As shown in FIG. 23A, the PM_{2.5} and PM_{10-2.5} removal efficiency is kept as high as 97˜99% and 99˜100%, respectively, while the pressure drop only increased less than 10 Pa. The particle removal efficiency of the PI filters were also tested in practical environments. As shown in FIGS. 23B and 23C, a PI filter with optical transmittance of 50% was used to remove the PM particles from the car exhaust gas. The temperature of the car exhaust usually ranges in 50˜80° C. A PM particle counter was used to measure the PM concentration in the exhaust gas before and after filtration. The PI filter kept stable under the strong blowing by the exhaust with a gas velocity of 2˜3 m/s. The PM concentrations in the exhaust before and after filtration were shown in Table 2, from which it can be seen that the PI filter can effectively remove all kinds of particles with sizes from <0.3 μm to >10 μm with very high efficiency. Especially, after filtration, the PM concentration of the exhaust was decreased to almost the same with that of ambient air, clearly showing the high filtration efficiency of PI nanofibrous filters at both room and high temperature.

TABLE 2
Performance of PI filter of removing PM particles from car exhaust gas

| d_{PM} (μm) | C_{before} (ft⁻³) | C_{after} (ft⁻³) | Cₐᵢᵣ (ft⁻³) | E (%) |
|---|---|---|---|---|
| 0.3 | 161104 | 7815 | 7146 | 99.56 |
| 0.5 | 456456 | 1296 | 1027 | 99.94 |
| 1.0 | 7511 | 112 | 103 | 99.88 |
| 2.5 | 633 | 33 | 25 | 98.68 |
| 5.0 | 113 | 14 | 13 | 99.0 |
| 10.0 | 9 | 3 | 3 | 100 |

Note:
d_{PM}: diameter of PM particles; C_{before}: PM concentration (particle number per square feet) in the car exhaust before filtration; C_{after}: PM concentration in the car exhaust after filtration; Cₐᵢᵣ: PM concentration in the ambient air; E: PM removal efficiency.

From the above demonstrations and comparisons, it is evident that PI nanofibrous air filters show excellent performance for high temperature filtration with high efficiency and low air pressure drop. As mentioned above, the polar chemical functional groups in PI molecules result in the strong binding affinity with PM_{2.5}. The dipole moment for the repeating units of PI (6.16 D) is much higher than that of PAN (3.6 D) and PVP (2.3 D), rendering PI with high PM_{2.5} removal efficiency. The PI nanofibers have a high thermal stability and can work in a wide range of temperature. The PI air filters have a high PM_{2.5} removal efficiency at both room and high temperature. Although the other filters made of different polymers such as PAN and PVP as well as some commercial air filters also have high PM removal efficiency, they are unstable and do not work at high temperatures. Besides, the commercial air filters have high pressure drop, thus will consume more energy when removing PM particles. In comparison, the PI filters have both of high removal efficiency and very low pressure drop. This will allow a high air flow through the filters and save a lot of energy when removing PM particles.

The reason for the PI nanofibrous air filters having such low pressure drop lies at least in the following three aspects. First, the nanofiber diameter is small and the PI air filters have a low thickness. The thickness of PI filters is in the range of 0.01˜0.1 mm compared to traditional fibers with thickness of 2˜30 mm. There is a lot of empty space between nanofibers. Second, nanofibers have a much higher available specific surface areas than microfibers, which provides more contact between the PM and the fibers. Third, when the diameter of the nanofibers is comparable to the mean free path of the air molecules (66 nm under normal conditions), the gas velocity is non-zero at the fiber surface due to “slip” effect. Because of the “slip” effect, the drag force from the nanofibers onto the air flow is greatly reduced, thus greatly reduces the pressure drop.

The long-term performance test shows that the PI air filters have a high PM particle removal efficiency and a long lifetime. The PI filters can effectively removal almost all the PM particles from the car exhaust at high temperature. The above performance proves that the PI nanofibrous air filters can be used as very effective high-efficiency air filters for high temperature PM_{2.5} particles removal. For the industrial application of PI air filters, they can work both independently and work together with the industrial dust collectors at both room and high temperature.

### WORKING EXAMPLES

### Example 1.1

### Electrospinning

The solution system for the polymers is 6 wt % polyacrylonitrile (PAN, MW=1.5×10⁵ g/mol, Sigma-Aldrich) in dimethylformamide (DMF, EMD Millipore), 7 wt % polyvinylpyrrolidone (PVP, MW=1.3×10⁶ g/mol, Acros) in ethanol (Fisher Scientific), 10 wt % polyvinyl alcohol (PVA, MW=9.5×10⁴ g/mol, Sigma-Aldrich) in distilled water, and 6 wt % polystyrene (PS, MW=2.8×10⁵ g/mol, Sigma-Aldrich) in DMF together with 0.1 wt % of myristyltrimethylammonium bromide (MTAB, Acros). The polymer solution was loaded in a 1-mL syringe with a 22-gauge needle tip which is connected to a voltage supply (ES30P-5W, Gamma High Voltage Research). The solution was pumped out of the needle tip using a syringe pump (KD Scientific). Fiber glass wire mesh (New York Wire) was sputter-coated (AJA International) with ˜150 nm of copper on both sides and was grounded to collect the electrospun nanofibers. The wire diameter was 0.011 inch, and the mesh size was 18×16. The electrospun nanofibers would lie across the mesh hole to form the air filter, similar to previous reports. The applied potential, the pump rate, the electrospinning duration, and the needle-collector distance were carefully adjusted to control the nanofiber diameter and the packing density.

### Example 1.2

### Optical Transmittance Measurement

The transmittance measurement used a xenon lamp (69911, Newport) as the light source, coupled with a monochromator (74125, Newport) to control the wavelength. An iris was used to trim the beam size to about 5 mm×5 mm before entering an integrating sphere (Newport) for transmittance measurement. A photodetector (70356, Newport) was inserted into one of the ports of integrating sphere. The photodiode is connected to lock-in radiometry system (70100 Merlin™, Newport) for photocurrent measurement. The samples were placed in front of the integrating sphere; therefore, both specular transmittance and diffuse transmittance were included. For air filters coated on copper wire mesh, a clean copper wire mesh with the same geometry was used as a reference. For self-standing filters, ambient air was used for reference. The transmittance spectrum was then weighted by AM1.5 solar spectrum from 400 to 800 nm to obtain the average transmittance.

### Example 1.3

### PM Generation and Efficiency Measurement

For all performance tests unless mentioned otherwise, model PM particles were generated from incense smoke by burning. The smoke PM particles has a wide size distribution from <300 nm to >10 μm with the majority particles <1 μm. The inflow concentration was controlled by diluting the smoke PM by air to a hazardous pollution level equivalent to PM_{2.5} index >300. PM particle number concentration was detected with and without filters by a particle counter (CEM) and the removal efficiency was calculated by comparing the number concentration before and after filtration. In the rigid PM capture test, dust PM particles were fabricated by grinding soil particles using a ball mill to submicron sizes. The pressure drop was measured by a differential pressure gauge (EM201B, UEi test instrument).

### Example 1.4

### Characterization

The SEM images and EDX was done by FEI XL30 Sirion SEM with acceleration voltage of 5 kV for imaging and 15 kV for EDX collection. The TEM images and EELS data were collected by FEI Titan TEM with acceleration voltage of 300 kV. The XPS spectrum was collected by PHI VersaProbe Scanning XPS Microprobe with Al Kα source. The FTIR spectrum was measured by Bruker Vertex 70 FTIR spectrometer.

### Example 2

### Electric Air Filter

### Example 2.1

### Material Synthesis Procedure for Cu-Sputtered Microfiber/Nanofiber

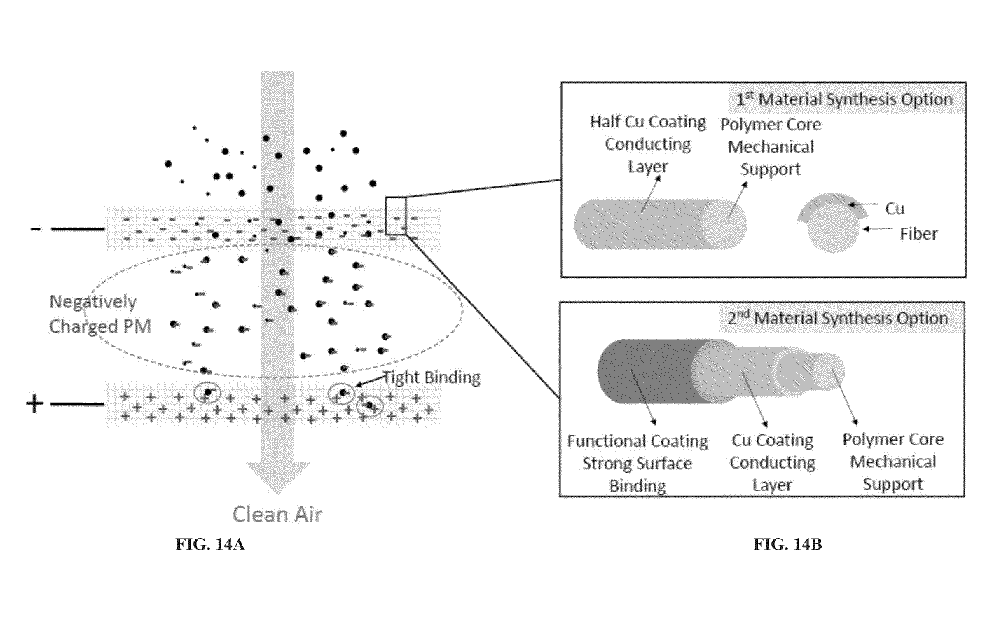

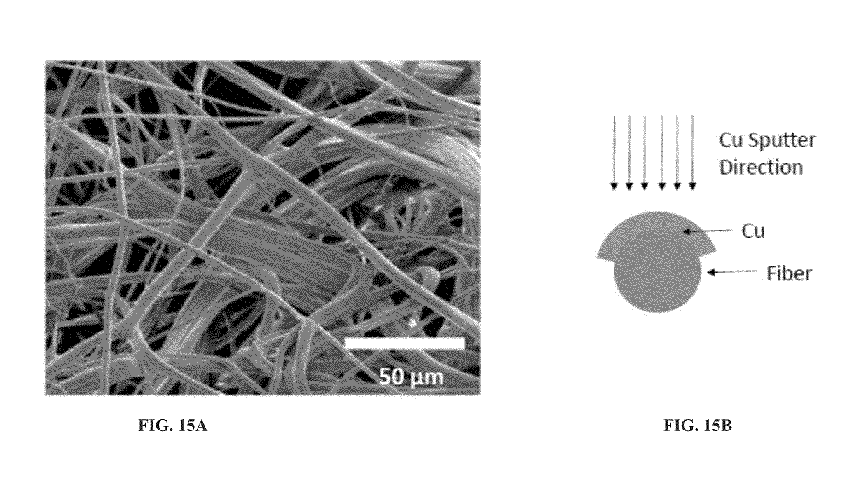

The microfibers were produced by peeling off the commercial polypropylene (PP) to 200-500 Nanofibers were made by electrospinning process. The polymer solution was loaded in a 1-mL syringe with a 22-gauge needle tip which is connected to a voltage supply (ES30P-5W, Gamma High Voltage Research). The solution was pumped out of the needle tip using a syringe pump (KD Scientific). The microfibers or nanofibers were sputter-coated (AJA International) with 50-300 nm of copper. See FIGS. 14A-14 and 15A-15B.

### Example 2.2

### Material Synthesis Procedure for Functionalized Cu-Coated Nanofiber

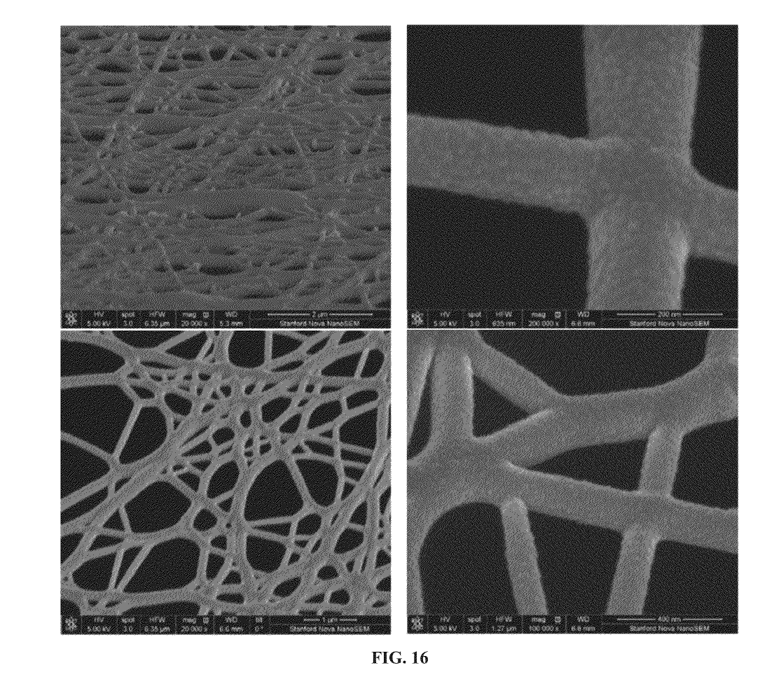

Core polymer nanofibers were synthesis by electrospinning process same as above. 50-300 nm of copper was coated by sputter. Then the nanofibers were air plasma treated to generate —OH group and linked with 3-cyanopropyltrichlorosilane through vapor surface modification. Other functional coating can be made through dip-coating from dilute polymer solutions. See FIGS. 14A-14B and 16.

### Example 2.3

### PM Generation and Efficiency Measurement

For all performance tests unless mentioned otherwise, model PM particles were generated from incense smoke by burning. The smoke PM particles has a wide size distribution from <300 nm to >10 μm with the majority particles <1 μm. The inflow concentration was controlled by diluting the smoke PM by air to a hazardous pollution level equivalent to PM_{2.5} index >300. PM particle number concentration was detected with and without filters by a particle counter (CEM) and the removal efficiency was calculated by comparing the number concentration before and after filtration. In the rigid PM capture test, dust PM particles were fabricated by grinding soil particles using a ball mill to submicron sizes. The pressure drop was measured by a differential pressure gauge (EM201B, UEi test instrument). Unless mentioned, the wind velocity used in the efficiency test was 0.21 m/s and the humidity was 30%.

### Example 2.4

### Filtration Experiment

Two identical conducting air filter electrodes were put parallel to each other. Inflow air carried high concentration of PM pollutant (>250 μg/m³). The wind velocity was 0.21 m/s. During filtration, voltages from 0-15 kV was added to the two conducting air filters. The removal efficiency was calculated by comparing the PM concentration in the inflow and outflow which was detected by a particle counter.

### Example 2.5

### Results

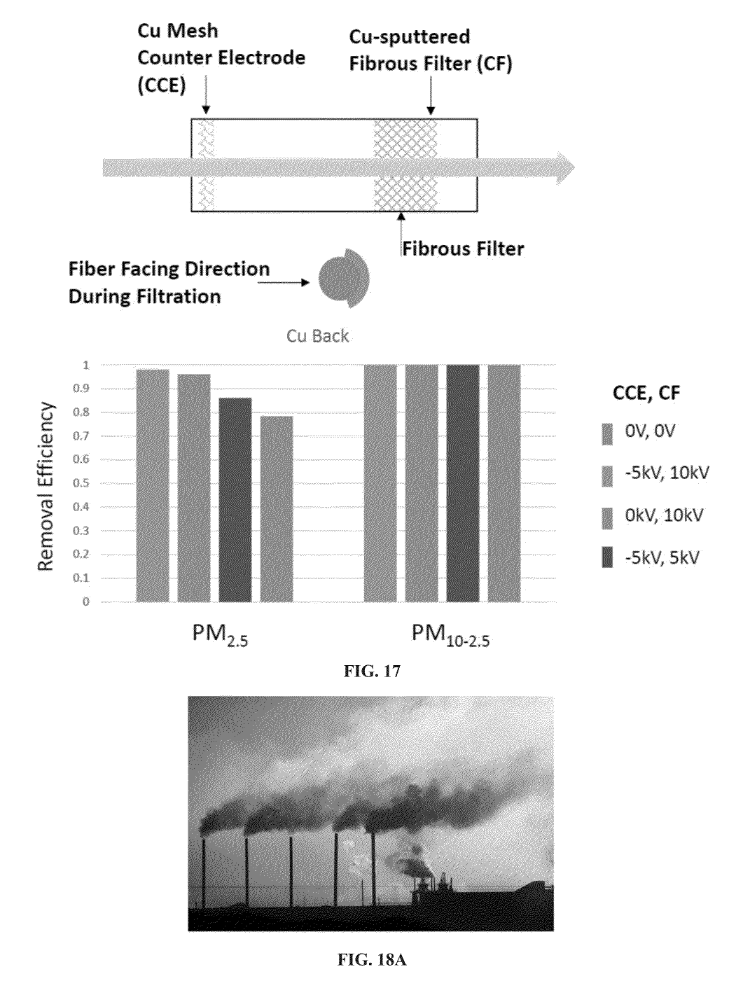

As show in FIG. 17, a negative voltage (0 to −10 kV) was added to the front electrode and a positive voltage was added to the back electrode (0 to +10 kV). Although microfibrous filter usually has insufficient efficiency of PM_{2.5} capture, when external voltage was applied, the efficiency increased significantly. For example, PM_{2.5} removal efficiency increased from 78.3% at 0 V to 98.0% at (−5 kV, 10 kV) or 96.0% at (0 V, 10 kV).

### Example 3.1

### Electrospinning

The solution system for the polymers used in this study was 15 wt % PI resin (CAS #62929-02-6, Alfa Aesar) in dimethylformamide (EMD Millipore), 6 wt % PAN (MW=1.5×10⁵ g/mol, Sigma-Aldrich) in dimethylformamide (EMD Millipore), 7 wt % polyvinypyrrolidone (MW=1.3×10⁶ g/mol, Across) in ethanol (Fisher Scientific). A 1-mL syringe with a 22-gauge needle tip was used to load the polymer solution and connected to a voltage supply (ES30P-5W, Gamma High Voltage Research). A syringe pump (KD Scientific) was used to pump the solution out of the needle tip using. The electrospun nanofibers were collected by a grounded copper mesh. The wire diameter of the copper mesh was 0.011 inch, and the mesh size was 18×16. During electrospinning, the nanofibers would lie across the mesh hole to form the air filter.

### Example 3.2

### PM Generation and Efficiency Measurement

The PM particles used in this work was generated by burning incense. The incense smoke PM particles had a wide size distribution from <300 nm to >10 μm, with the majority of particles being <1 μm. By diluting the smoke PM by air, the inflow concentration was controlled to a hazardous pollution level equivalent to the PM_{2.5} index >300. A particle counter (CEM) was used to detect the PM particle number concentration before and after filtration. The removal efficiency was calculated by comparing the number concentration before and after filtration.

### Example 3.3

### High Temperature Filtration Measurement

The high temperature filtration measurement was conducted on an electrical tube furnace (Lindberg/Blue). First, a PI filter was coated by copper tape on the edge. Then the filter was placed between two stainless steel pipe flanges and fixed firmly with screws. Then the pipe flanges were connected into the filtration measurement system and placed inside the tube furnace. A PM particle counter (CEM) was used to measure the particle number concentration. For each temperature, the filter was kept for 20 min to be stabilized.

### Example 3.4

### Optical Transmittance Measurement

The optical transmittance measurement was conducted as follows. A xenon lamp (69911, Newport) was used as the light source, coupled with a monochromator (74125, Newport) to control the wavelength. The beam size was trimmed by an iris to ˜5 mm×5 mm before entering an integrating sphere (Newport) for transmittance measurement. A photodiode was connected to lock-in radiometry system (70100 Merlin, Newport) for photocurrent measurement. A photodector (70356, Newport) was inserted into one of the ports of integrating sphere. The filter samples were placed in front of the integrating sphere. Both specular transmittance and diffuse transmittance were included. For air filters collected on copper mesh, a clean copper mesh with the same geometry was used as a reference. For self-standing filters, ambient air was used for reference. The transmittance spectrum was weighted by AM1.5 solar spectrum from 400 to 800 nm to obtain the average transmittance.

### Example 3.5

### Pressure Drop Measurement

The pressure drop was measured by a differential pressure gauge (EM201B, UEi test instrument).

### Example 3.6

### Characterization

The SEM images were taken by FEI XL30 Sirion SEM with an acceleration voltage of 5 kV for imaging.

### Embodiment 1

An air filter comprising a substrate and a network of polymeric nanofibers deposited on the substrate, wherein the air filter has a light transmittance of at least 50% and a removal efficiency for PM_{2.5} of at least 70%.

### Embodiment 2

The air filter of Embodiment 1, wherein the polymeric nanofibers comprise a polymer comprising a repeating unit having a dipole moment of at least 2 D.

### Embodiment 3

The air filter of Embodiment 1, wherein the polymeric nanofibers comprise a polymer comprising a repeating unit having a dipole moment of at least 3 D.

### Embodiment 4

The air filter of any of Embodiments 1-3, wherein the polymeric nanofibers comprise a polymer comprising a repeating unit which comprises a nitrile group.

### Embodiment 5

The air filter of any of Embodiments 1-4, wherein the polymeric nanofibers comprise polyacrylonitrile.

### Embodiment 6

The air filter of any of Embodiments 1-5, wherein the polymeric nanofibers have an average diameter of 10-900 nm.

### Embodiment 7

The air filter of any of Embodiments 1-6, wherein the polymeric nanofibers have an average diameter of 50-500 nm.

### Embodiment 8

The air filter of any of Embodiments 1-7, wherein the polymeric nanofibers are electrospun onto the substrate.

### Embodiment 9

The air filter of any of Embodiments 1-8, wherein the air filter has a light transmittance of at least 70%.

### Embodiment 10

The air filter of any of Embodiments 1-9, wherein the air filter has a removal efficiency for PM_{2.5} of at least 90%.

### Embodiment 11

The air filter of any of Embodiments 1-10, wherein the air filter has a removal efficiency for PM_{10-2.5} of at least 90%.

### Embodiment 12

The air filter of any of Embodiments 1-11, wherein the air filter has a removal efficiency for PM_{2.5} of at least 90% at a relative humidity of 70%.

### Embodiment 13

The air filter of any of Embodiments 1-12, wherein the air filter has a removal efficiency for PM_{2.5} of at least 90% after 100 hours of exposure to air having an average PM_{2.5} index of 300 and an average wind speed of 1 mile/hour.

### Embodiment 14

A passive air filtering device comprising the air filter of any of Embodiments 1-13.

### Embodiment 15

A window screen comprising the air filter of any of Embodiments 1-13.

### Embodiment 16

A wearable mask comprising the air filter of any of Embodiments 1-13.

### Embodiment 17

A method for making the air filter of any of Embodiments 1-13, comprising electrospinning the polymeric nanofibers onto the substrate from a polymer solution.

### Embodiment 18

The method of Embodiment 17, wherein the polymer solution comprises 1-20 wt. % of the polymer.

### Embodiment 19

A method for making an air filtering device, comprising incorporating the air filter of any of Embodiments 1-13 into a window screen.

### Embodiment 20

A method for making an air filtering device, comprising incorporating the air filter of any of Embodiments 1-13 into a wearable mask.

### Embodiment 21

An electric air filter comprising a first layer adapted to receive a first electric voltage, wherein the first layer comprises an organic fiber coated with a conductive material.

### Embodiment 22

The electric air filter of Embodiment 21, wherein the organic fiber is partially coated with the conductive material.

### Embodiment 23

The electric air filter of Embodiment 22, wherein the organic fiber is a microfiber or nanofiber, and wherein the conductive material is selected from metal, metal oxide, and conductive polymer.

### Embodiment 24

The electric air filter of Embodiment 22, wherein the organic fiber comprises a coated side and a uncoated side, and wherein the uncoated side faces direction of air flow.

### Embodiment 25

The electric air filter of Embodiment 21, wherein the organic fiber is coated with the conductive material, and wherein the conductive material is surface functionalized.

### Embodiment 26

The electric air filter of Embodiment 25, wherein the organic fiber is a microfiber or nanofiber, wherein the conductive material is selected from metal, metal oxide, and conductive polymer, and wherein the conductive material is surface functionalized with a polar group to increase affinity for PM_{2.5}.

### Embodiment 27

The electric air filter of any of Embodiments 21-26, further comprising a second layer adapted to receive a second electric voltage.

### Embodiment 28

A ventilation system comprising the electric air filter of any of Embodiments 21-27.

### Embodiment 29

An air-conditioning system comprising the electric air filter of any of Embodiments 21-27.

### Embodiment 30

An automotive cabin air filter comprising the electric air filter of any of Embodiments 21-27.

### Embodiment 31

A window screen comprising the electric air filter of any of Embodiments 21-27.

### Embodiment 32

A method for making the electric air filter of any of Embodiments 21-27, comprising sputter coating a metal or metal oxide onto a microfiber or nanofiber.

### Embodiment 33

The method of Embodiment 32, wherein the sputter coating is directional, and wherein the microfiber or nanofiber is partially coated with the metal or metal oxide.

### Embodiment 34

A method for making the electric air filter any of Embodiments 21-27, comprising treating a microfiber or nanofiber coated with a metal or metal oxide to generate a reactive group, and reacting said reactive group with an organic compound to functionalize surface of the metal or metal oxide coating to increase affinity for PM_{2.5}.

### Embodiment 35

The method of Embodiment 34, wherein the microfiber or nanofiber coated with the metal or metal oxide is treated with air plasma to generate —OH group, and wherein the —OH group is reacted with a silane derivative.

### Embodiment 36

A method for filtering PM_{2.5} using the electric air filter of any of Embodiments 21-27, comprising applying an electric voltage on the first layer of the electric air filter.

### Embodiment 37

The method of Embodiment 36, wherein the first electric voltage is a positive voltage.

### Embodiment 38

The method of Embodiment 36, wherein the first electric voltage is a negative voltage.

### Embodiment 39

A method for filtering PM_{2.5} using the electric air filter of Embodiment 24, comprising applying an electric voltage on the first layer of the electric air filter, and placing the electric air filter to allow the uncoated side to face the direction of air flow.

### Embodiment 40

A method for filtering PM_{2.5} using the electric air filter of Embodiment 27, comprising applying a first electric voltage on the first layer, and applying a second electric voltage on the second layer, wherein the first electric voltage and the second electric voltage have opposite polarity.

### Embodiment 41

An air filter for high temperature filtration, comprising a substrate and a network of polymeric nanofibers deposited on the substrate, wherein the air filter has a removal efficiency for PM_{2.5} of at least 70% at an operating temperature of 200° C.

### Embodiment 42

The air filter of Embodiment 41, wherein the polymeric nanofibers comprise a polymer comprising a repeating unit having a dipole moment of at least 3 D.

### Embodiment 43

The air filter of Embodiment 41, wherein the polymeric nanofibers comprise a polymer comprising a repeating unit having a dipole moment of at least 6 D.

### Embodiment 44

The air filter of any of Embodiments 41-43, wherein the polymeric nanofibers comprise a polymer selected from polyimide, poly(p-phenylene sulfide), polyacrylonitrile, poly-p-phenylene terephthalamide, polytetrafluoroethylene, and derivatives thereof.

### Embodiment 45

The air filter of any of Embodiments 41-44, wherein the polymeric nanofibers comprise polyimide.

### Embodiment 46

The air filter of any of Embodiments 41-45, wherein the polymeric nanofibers have an average diameter of 10-900 nm.

### Embodiment 47

The air filter of any of Embodiments 41-46, wherein the polymeric nanofibers have an average diameter of 50-500 nm.

### Embodiment 48

The air filter of any of Embodiments 41-47, wherein the polymeric nanofibers are electrospun onto the substrate.

### Embodiment 49

The air filter of any of Embodiments 41-48, wherein the air filter has a light transmittance of at least 30%.

### Embodiment 50

The air filter of any of Embodiments 41-49, wherein the air filter has a removal efficiency for PM_{2.5} of at least 80% at an operating temperature of 200° C.

### Embodiment 51

The air filter of any of Embodiments 41-50, wherein the air filter has a removal efficiency for PM_{10-2.5} of at least 80% at an operating temperature of 200° C.

### Embodiment 52

The air filter of any of Embodiments 41-51, wherein the air filter has a pressure drop of 100 Pa or less at a gas velocity of 0.2 m/s.

### Embodiment 53

The air filter of any of Embodiments 41-52, wherein the air filter has a removal efficiency for PM_{2.5} of at least 80% after 100 hours of exposure to air an average PM_{2.5} index of 300 and an average wind speed of 0.2 m/s at an operating temperature of 200° C.

### Embodiment 54

An air filtering device for removing high temperature PM_{2.5} particles from pollution sources comprising the air filter of any of Embodiments 41-53.

### Embodiment 55

A vehicle exhaust filter comprising the air filter of any of Embodiments 41-53.

### Embodiment 56

An industrial exhaust filter or a powder plant exhaust filter comprising the air filter of any of Embodiments 41-53.

### Embodiment 57

A method for making the air filter of any of Embodiments 41-53, comprising electrospinning the polymeric nanofibers onto the substrate from a polymer solution.

### Embodiment 58

The method of Embodiment 57, wherein the polymer solution comprises 1-30 wt. % of the polymer.

### Embodiment 59

A method for making an air filtering device, comprising incorporating the air filter of any of Embodiments 41-53 into a vehicle exhaust filter.

### Embodiment 60

A method for making an air filtering device, comprising incorporating the air filter of any of Embodiments 41-53 into an industrial exhaust filter or a power plant exhaust filter.

As used herein, the singular terms “a,” “an,” and “the” include plural referents unless the context clearly dictates otherwise. Thus, for example, reference to a molecule can include multiple molecules unless the context clearly dictates otherwise.

As used herein, the terms “substantially,” “substantial,” and “about” are used to describe and account for small variations. When used in conjunction with an event or circumstance, the terms can refer to instances in which the event or circumstance occurs precisely as well as instances in which the event or circumstance occurs to a close approximation. For example, the terms can refer to less than or equal to ±10%, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified. For example, a ratio in the range of about 1 to about 200 should be understood to include the explicitly recited limits of about 1 and about 200, but also to include individual ratios such as about 2, about 3, and about 4, and sub-ranges such as about 10 to about 50, about 20 to about 100, and so forth.

In the foregoing description, it will be readily apparent to one skilled in the art that varying substitutions and modifications may be made to the invention disclosed herein without departing from the scope and spirit of the invention. The invention illustratively described herein suitably may be practiced in the absence of any element or elements, limitation or limitations, which is not specifically disclosed herein. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention. Thus, it should be understood that although the present invention has been illustrated by specific embodiments and optional features, modification and/or variation of the concepts herein disclosed may be resorted to by those skilled in the art, and that such modifications and variations are considered to be within the scopes of this invention.

What is claimed is:

1. An air filter comprising a substrate and a network of polymeric nanofibers deposited on the substrate, wherein the air filter has a removal efficiency for PM_{2.5} of at least 70% when a light transmittance through the filter is below 50%.

2. The air filter of claim 1, wherein the polymeric nanofibers comprise a polymer comprising a repeating unit having a dipole moment of at least 1 D.

3. The air filter of claim 1, wherein the polymeric nanofibers comprise a polymer comprising a repeating unit having a dipole moment of at least 2 D.

4. The air filter of claim 1, wherein the polymeric nanofibers comprise a polymer comprising a repeating unit having a dipole moment of at least 3 D.

5. The air filter of claim 1, wherein the polymeric nanofibers comprise polyacrylonitrile.

6. The air filter of claim 1, wherein the polymeric nanofibers comprise nylon.

7. The air filter of claim 1, wherein the polymeric nanofibers have an average diameter of 10-900 nm.

8. The air filter of claim 1, wherein the polymeric nanofibers have positive or negative net electric charge.

9. The air filter of claim 1, wherein the air filter has a removal efficiency for PM_{2.5} of at least 90%, and a removal efficiency for PM_{10-2.5} of at least 90% when a light transmittance is below 70%.

10. The air filter of claim 1, wherein the air filter has a removal efficiency for PM_{2.5} of at least 90% after 100 hours of exposure to air having an average PM_{2.5} index of 300 and an average wind speed of 1 mile/hour.

11. The air filter of claim 1, wherein other materials are added onto polymer nanofibers to provide more functionality.

12. An air filtering device comprising the air filter of claim 1.

13. The air filtering device of claim 12, which is incorporated into a window screen, a wearable mask, an indoor air filtration unit, a building air conditioning and ventilation system, a car air condition system, a car exhaust system, an industrial exhaust system, a clean room air filtration system, a cigarette filter, or an outdoor filtration system.

14. A method for making the air filter of claim 1, comprising electrospinning the polymeric nanofibers onto the substrate from a polymer solution comprising 1-20 wt. % of a polymer comprising a repeating unit having a dipole moment of at least 1 D, or at least 2 D, or at least 3 D.

15. A method for making an air filtering device, comprising incorporating the air filter of claim 1 into a window screen, a wearable mask, an indoor air filtration unit, a building air conditioning and ventilation system, a car air condition system, a car exhaust system, an industrial exhaust system, a clean room air filtration system, a cigarette filter, or an outdoor filtration system.

16. An electric air filter comprising a first layer adapted to receive a first electric voltage, wherein the first layer comprises an organic fiber coated with a conductive material.

17. The electric air filter of claim 16, wherein the organic fiber is a microfiber or nanofiber, wherein the organic fiber is partially coated with the conductive material, and wherein the conductive material is selected from carbon, metal, metal oxide, metal nitride, metal carbide and conductive polymer.

18. The electric air filter of claim 17, wherein the organic fiber comprises a coated side and a uncoated side, and wherein the uncoated side faces direction of air flow.

19. The electric air filter of claim 16, wherein the organic fiber is a microfiber or nanofiber, wherein the organic fiber is coated with the conductive material, wherein the conductive material is selected from carbon, metal, metal oxide, metal nitride, metal carbide and conductive polymer, and wherein the conductive material is surface functionalized with a polar group to increase affinity for PM_{2.5}.

20. The electric air filter of claim 16, further comprising a second layer adapted to receive a second electric voltage.

21. An air filtering system comprising the electric air filter of claim 16.

22. The air filtering system of claim 21, which is selected from a ventilation system, an air-conditioning system, and an automotive cabin air filter.

23. A method for making the electric air filter of claim 16, comprising sputter coating a metal or metal oxide onto a microfiber or nanofiber, wherein the sputter coating is directional, and wherein the microfiber or nanofiber is partially coated with the metal or metal oxide.

24. A method for making the electric air filter of claim 16, comprising treating a microfiber or nanofiber coated with a metal or metal oxide to generate a reactive group, and reacting said reactive group with an organic compound to functionalize surface of the metal or metal oxide coating to increase affinity for PM_{2.5}.

25. A method for filtering PM_{2.5} using the electric air filter of claim 16, comprising applying an electric voltage on the first layer of the electric air filter.

26. An air filter for high temperature filtration, comprising a substrate and a network of polymeric nanofibers deposited on the substrate, wherein the air filter has a removal efficiency for PM_{2.5} of at least 70% at an operating temperature of at least 70° C.

27. The air filter of claim 26, wherein the polymeric nanofibers comprise a polymer comprising a repeating unit having a dipole moment of at least 1 D, or at least 2 D, or at least 3 D.

28. The air filter of claim 26, wherein the polymeric nanofibers comprise polyimide.

29. The air filter of claim 26, wherein the polymeric nanofibers have an average diameter of 10-900 nm.

30. The air filter of claim 26, wherein the air filter has a pressure drop of 500 Pa or less at a gas velocity of 0.2 m/s, a removal efficiency for PM_{2.5} of at least 80% at an operating temperature of at least 70° C., and a removal efficiency for PM_{10-2.5} of at least 80% at an operating temperature of at least 70° C.

31. The air filter of claim 26, wherein the air filter has a removal efficiency for PM_{2.5} of at least 80% after 100 hours of exposure to air having an average PM_{2.5} index of 300 and an average wind speed of 0.2 m/s at an operating temperature of at least 70° C.

32. An air filtering device for removing high temperature PM_{2.5} particles from pollution sources comprising the air filter of claim 26.

33. An air filtering device of claim 32, which is selected from a vehicle exhaust filter, an industrial exhaust filter, and a power plant exhaust filter.

34. A method for making the air filter of claim 26, comprising electrospinning the polymeric nanofibers onto the substrate from a polymer solution comprising 1-30 wt. % of a polymer comprising a repeating unit having a dipole moment of at least 1 D.

35. A method for making an air filtering device for removing high temperature PM_{2.5} particles from pollution sources, comprising incorporating the air filter of claim 26 into a vehicle exhaust filter, an industrial exhaust filter, or a power plant exhaust filter.
